(19) United States
(12) Patent Application Publication
(10) Pub. No.: US 2025/0212507 A1
(43) Pub. Date: Jun. 26, 2025

(54) CMOS METAL CONTACTS WITH DOPANT DIFFUSION BARRIERS

(71) Applicant: Intel Corporation, Santa Clara, CA (US)

(72) Inventors: Gilbert Dewey, Beaverton, OR (US); Nancy Zelick, Portland, OR (US); Ilya V. Karpov; Christopher Jezewski, Portland, OR (US); Siddharth Chouksey, Portland, OR (US); Thoe Kathy Michaelos, Portland, OR (US); Nazila Haratipour, Portland, OR (US); Arnab Sen Gupta, Hillsboro, OR (US); I-Cheng Tung, Hillsboro, OR (US); Matthew V. Metz, Portland, OR (US)

(73) Assignee: Intel Corporation, Santa Clara, CA (US)

(21) Appl. No.: 18/390,235

(22) Filed: Dec. 20, 2023

(51) Int. Cl. H01L 27/092; H01L 29/06; H01L 29/40; H01L 29/423; H01L 29/45; H01L 29/775; H01L 29/786

(52) U.S. Cl. CPC H10D 84/853; H10D 30/43; H10D 30/6735; H10D 30/6757; H10D 62/121; H10D 62/83; H10D 64/01; H10D 64/62

(57) ABSTRACT

Contacts to n-type and p-type source/drain regions in complementary metal-oxide semiconductor (CMOS) technologies comprise a diffusion barrier layer positioned between the contact metal and the source/drain regions. The contact metal-diffusion barrier layer pairs used to contact n-type and p-type source/drain regions can comprise different materials. The contact metal layers used in n-type and p-type source/drain contacts can comprise the same or different materials. The presence of diffusion barrier layers can provide for thermally stable low resistance source/drain contacts by inhibiting dopant diffusion from the source/drain regions to the contact metal.

### BACKGROUND

Metal contacts can be used to provide electrically conductive connections to source/drain regions of field-effect transistors. Metal contacts have an associated parasitic resistance that, if large enough, can affect transistor performance.

### BRIEF DESCRIPTION OF THE DRAWINGS

FIGS. 1A-1B are simplified perspective views of an example planar field-effect transistor (FET) comprising metal contacts to source/drain contacts that comprise a diffusion barrier layer.

FIG. 1C is a cross-sectional view of the example planar FET of FIGS. 1A-1B taken along plane A of FIG. 1A.

FIG. 1D is a cross-sectional view of the example planar FET of FIGS. 1A-1B taken along plane B of FIG. 1B.

FIGS. 2A-2B are simplified perspective views of an example FinFET comprising source/drain contacts with a diffusion barrier layer.

FIGS. 2C-2D are cross-sectional views of the example FinFET of FIGS. 2A-2B taken along plane C of FIG. 2A.

FIG. 2E is a cross-sectional view of the example FinFET of FIGS. 2A-2B taken along plane D of FIG. 2B.

FIGS. 3A-3B are simplified perspective views of a first example GAAFET comprising source/drain contacts with a diffusion barrier layer.

FIG. 3C is a cross-sectional view of the example GAAFET of FIGS. 3A-3B taken along plane E of FIG. 3A.

FIG. 3D is a cross-sectional view of the source semiconductor region of FIGS. 3A-3B taken along plane F of FIG. 3B.

FIGS. 4A-4B are simplified perspective views of a second example GAAFET comprising source/drain contacts with a diffusion barrier layer.

FIGS. 4C-4D are cross-sectional views of the GAAFET of FIGS. 4A-4B taken along plane G of FIG. 4A.

FIG. 4E is a cross-sectional view of the GAAFET of FIGS. 4A-4B taken along plane H of FIG. 4B.

FIGS. 5A-5H illustrate an example simplified process sequence for forming n-type and p-type contacts comprising a diffusion barrier layer.

FIG. 6 is an example method of forming metal source/drain contacts comprising a diffusion barrier layer to contact n-type and p-type source/drain regions.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIGS. 9A-9D are perspective views of example planar, FinFET, gate-all-around, and stacked gate-all-around transistors.

FIGS. 10A and 10B are perspective and cross-sectional views of example forksheet gate-all-around transistors.

FIGS. 11A and 11B are perspective and cross-sectional views of an example complementary field-effect-transistor (CFET) architecture.

FIG. 12 is a cross-sectional side view of an integrated circuit device assembly that may include a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

Metal contacts to MOSFET (metal-oxide-semiconductor field-effect transistor (FET)) source/drain regions can be thermally unstable in that their resistance (contact resistance) can increase after being subjected to high-temperature processing steps that occur during integrated circuit fabrication after source/drain region formation. These back end of line (BEOL) process steps can involve numerous annealing and other high-temperature processing steps that can cause the outdiffusion of dopants from the source/drain region into the contact metal, resulting in dopant depletion in the source/drain region at the interface between the source/drain region and the contact metal. These high-temperature processes can also cause the deactivation of dopants, the movement of dopants off of a crystal lattice substitutional site of the semiconductor, in the source/drain region. Silicide formation at the contact-source/drain region interface can also catalyze dopant outdiffusion and the deactivation of dopants in source/drain regions. Dopant outdiffusion and deactivation are understood to be at least partially responsible for metal contact thermal instability. The increased resistance of source/drain contacts due to their thermal instability can impact transistor performance in the form of, for example, reduced drive current. The impact of parasitic contact resistance on device performance can increase in successive semiconductor manufacturing technologies as transistor dimensions continue to shrink.

Described herein are metal contacts that comprise a diffusion barrier layer between the contact metal and the source/drain regions of field effect transistors. These metal contacts can comprise different contact metals for n-type contacts (contacts that contact n-type source/drain regions) and p-type contacts (contacts that contact p-type source/drain regions). These metal contacts can thus be used in complementary metal-oxide semiconductor (CMOS) integrated circuit manufacturing technologies. Diffusion barrier layers can aid in forming low-resistance contacts that are thermally stable by reducing or inhibiting the diffusion of dopants from source/drain contact regions into the contact metal layer. This can prevent dopant depletion at the contact metal-semiconductor interface and the deactivation of dopants in the source/drain regions. The diffusion barrier layers can also reduce metal silicide formation in source/drain regions by limiting the amount of contact metal that diffuses from the contact metal layer into source/drain regions, which can further serve to reduce contact resistance. Contact metal layer-diffusion barrier layer pairs used in n-type contacts can comprise different materials than those used in contact metal layer-diffusion barrier layer pairs used in p-type contacts, allowing for the contact resistance in n-type and p-type contacts to be independently tailored. In some embodiments, the contact metal layers in n-type and p-type contacts can comprise the same material or comprise metal compounds that have the same metal by elemental composition (e.g., both are metal compounds with titanium as the metal, both are metal compounds with molybdenum as the metal), and the diffusion barrier layers in n-type and p-type contacts are made of different materials. The selection of material used for a diffusion barrier layer can be based in part on the material's work function. The metal contact technologies disclosed herein can be used in planar FETs, tri-gate transistors (e.g., FinFETs), gate-all-around field-effect transistors (GAAFETs, such as nanosheet, nanowire, and nanoribbon transistors), and other transistor architectures, such as complementary FET (CFET) and forksheet transistor architectures. By reducing parasitic contact resistance, the technologies disclosed herein can enable increased transistor performance, faster processor speeds, and contact architectures that are more scalable than existing ones.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, a sidewall portion of a layer that is substantially perpendicular to a bottom portion of a layer or a substrate surface includes sidewalls that are within 20 degrees of perpendicular to the bottom portion of the layer or substrate surface, and a first surface that is substantially parallel to a second surface can include a first surface that is within several degrees of parallel from the second surface. Values modified by the word “about” include values with +/−10% of the listed values and values listed as being within a range include those within a range from 10% less than the listed lower range limit and 10% greater than the listed higher range limit.

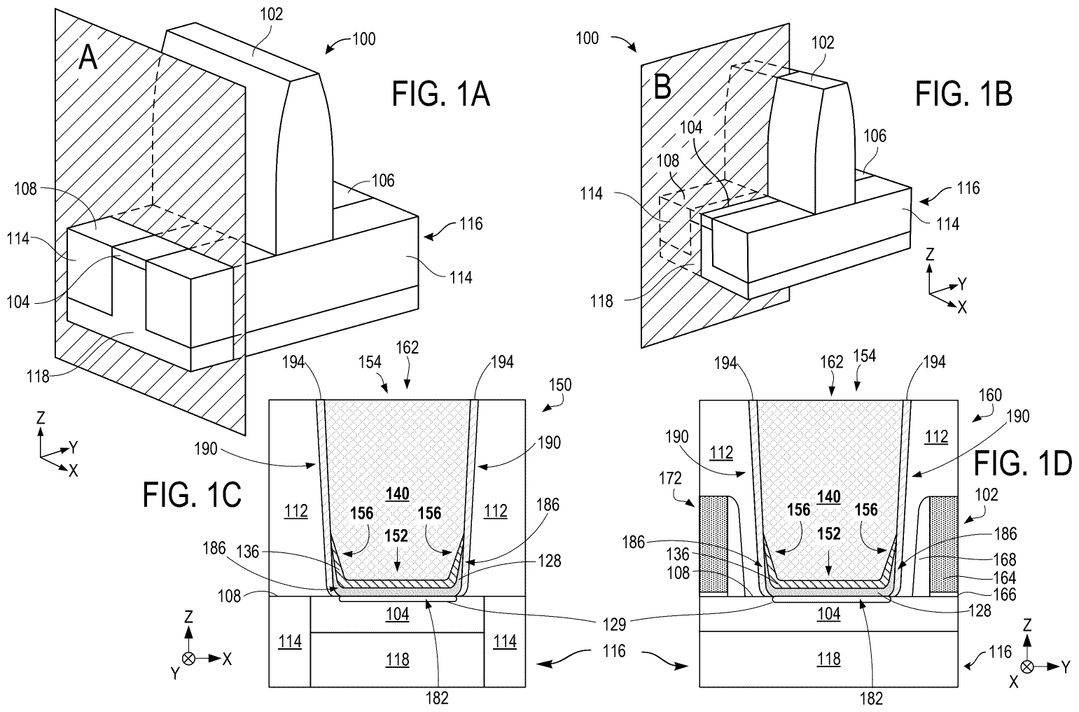

As used herein, the phrase “located on” in the context of a first layer or component located on a second layer or component refers to the first layer or component being directly physically attached to the second part or component (there are no layers or components between the first and second layers or components) or physically attached to the second layer or component via one or more intervening layers or components. For example, with reference to FIG. 1C, the bottom portion 152 of the contact metal layer 136 is located on the source region 104 with an intervening bottom portion 182 of diffusion barrier layer 128.

As used herein, the term “positioned adjacent” refers to layers or components that are in physical contact with each other. That is, there is no layer or component between the stated adjacent layers or components. For example, a layer X that is positioned adjacent to a layer Y refers to a layer that is in physical contact with layer Y.

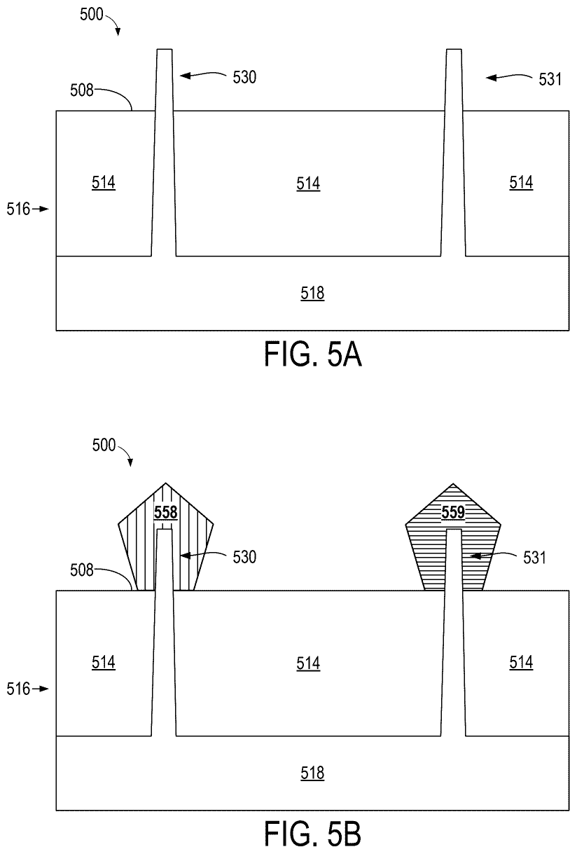

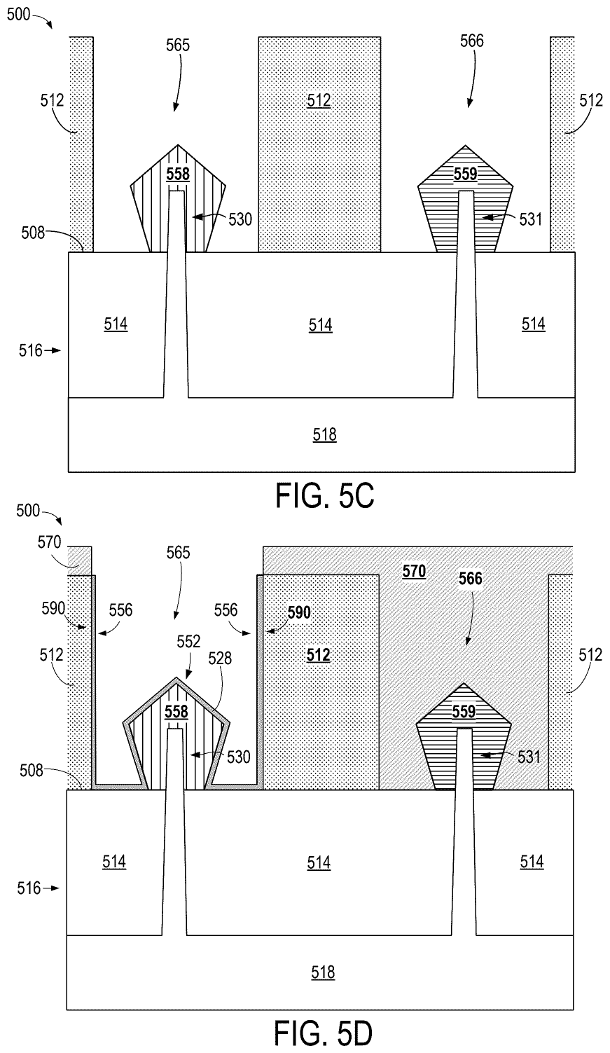

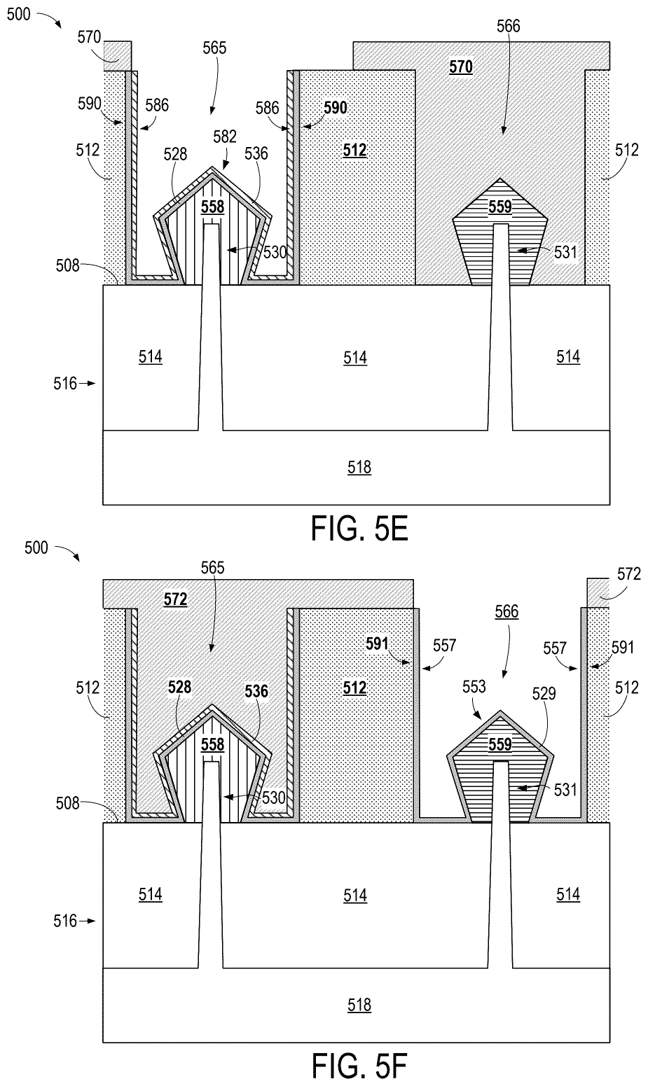

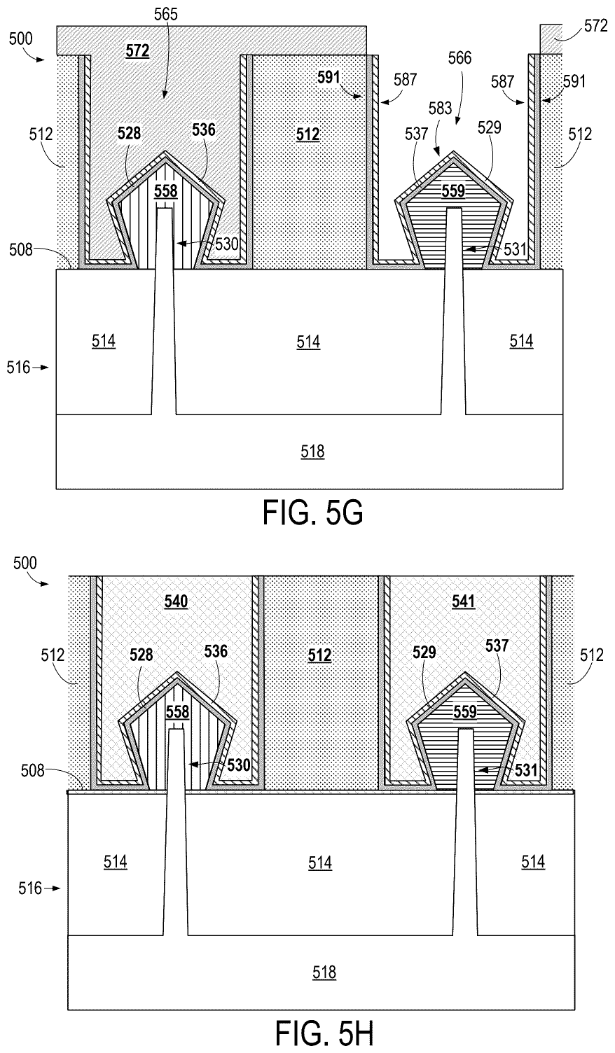

As used herein, the term “layer” can refer to one or more physically separate portions of a feature that are formed simultaneously during integrated circuit die fabrication. For example, with reference to FIG. 5A, dielectric layer 514, as illustrated, comprises three separate portions-one to the left of fin 530, one between fins 530 and 531, and one to the right of fin 531. The term “layer” can also refer to a subset of all physically separate portions of a feature formed simultaneously during fabrication. For example, portions of the fill metal formed in contact holes 545 and 546 simultaneously during fabrication can be referred to as separate layers (fill metal layer 540, fill layer 541).

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

FIGS. 1A-1B are simplified perspective views of an example planar field-effect transistor (FET) comprising metal contacts to source/drain contacts that comprise a diffusion barrier layer. Transistor 100 is formed on a substrate 116 and comprises a gate 102, a source region 104, and a drain region 106. The substrate 116 comprises a surface 108, a bulk region 118, and isolation regions 114 that separate source region 104 and drain region 106 from source/drain regions of other transistors. The transistor 100 is planar in that the source region 104 and the drain region 106 are planar with respect to the surface 108 of the substrate 116. The substrate 116 can comprise any substrate described or referenced herein, or any other substrate upon which transistors can be formed.

FIG. 1C is a cross-sectional view of the example planar FET of FIGS. 1A-1B taken along plane A of FIG. 1A. Plane A cuts across the source region 104 of transistor 100. FIG. 1D is a cross-sectional view of the example planar FET of FIGS. 1A-1B taken along plane B of FIG. 1B. Plane B extends along the source region 104 of transistor 100 in a direction perpendicular to plane A. Cross-sectional views 150 and 160 illustrate a contact 154 contacting the source region 104. FIG. 1D illustrates the contact 154 positioned between gate 102 and a second gate 172 belonging to a second transistor (not shown in FIGS. 1A-1B). The contact 154 is positioned within a hole 162 in a dielectric layer 112 and comprises a fill (or trench, plug) metal layer 140, a contact metal layer 136, and a diffusion barrier layer 128. The dielectric layer 112 isolates the contact 154 from adjacent contacts and/or other features.

A portion 152 of the contact metal layer 136 is located on the source region 104 and portions 156 of the contact metal layer 136 are not located on the source region 104. The portion 152 of the contact metal layer 136 can be referred to as a bottom portion of the contact metal layer 136 and the portions 156 can be referred to as sidewall portions of the contact metal layer 136. In some embodiments, the sidewall portions 156 are substantially perpendicular to the bottom portion 152. A portion 182 of the diffusion barrier layer 128 is positioned adjacent to the source region 104 and portions 186 of the diffusion barrier layer 128 are not positioned adjacent to the source region 104. The portion 182 of the diffusion barrier layer 128 can be referred to as a bottom portion of the diffusion barrier layer 128 and the portions 186 can be referred to as sidewall portions of the diffusion barrier layer 128. In some embodiments, the sidewall portions 186 are substantially perpendicular to the bottom portion 182.

The contact metal layer 136 is positioned adjacent to at least a portion of the diffusion barrier layer 128 and is positioned adjacent to at least a portion of the fill metal layer 140. The diffusion barrier layer 128 and the contact metal layer 136 layer are positioned within a contact hole (or cavity) 162 in the dielectric layer 112 and the fill metal layer 140 at least partially fills the contact hole 162. The contact hole 162 comprises sidewalls 190.

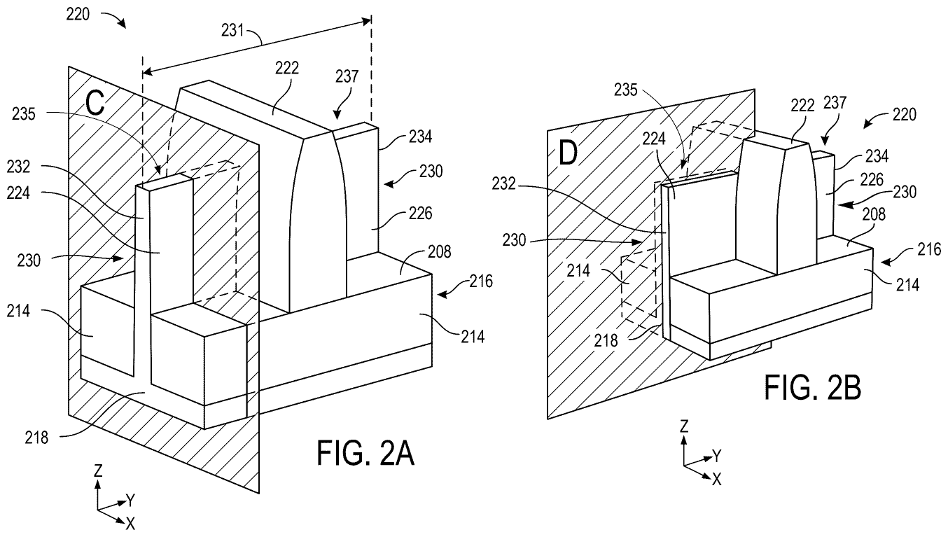

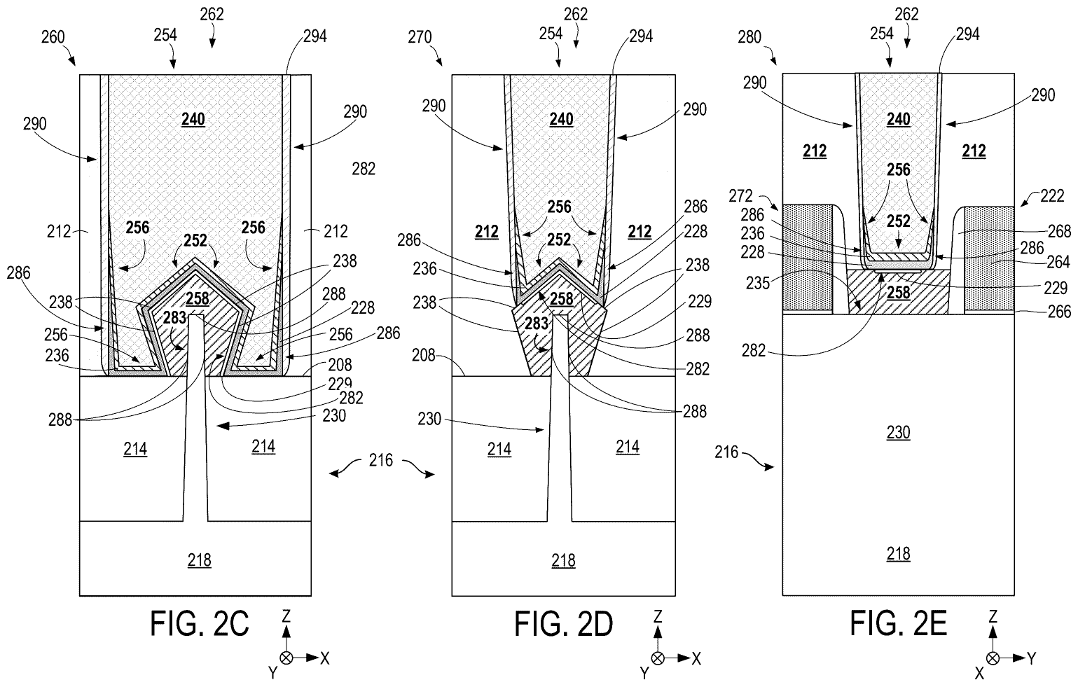

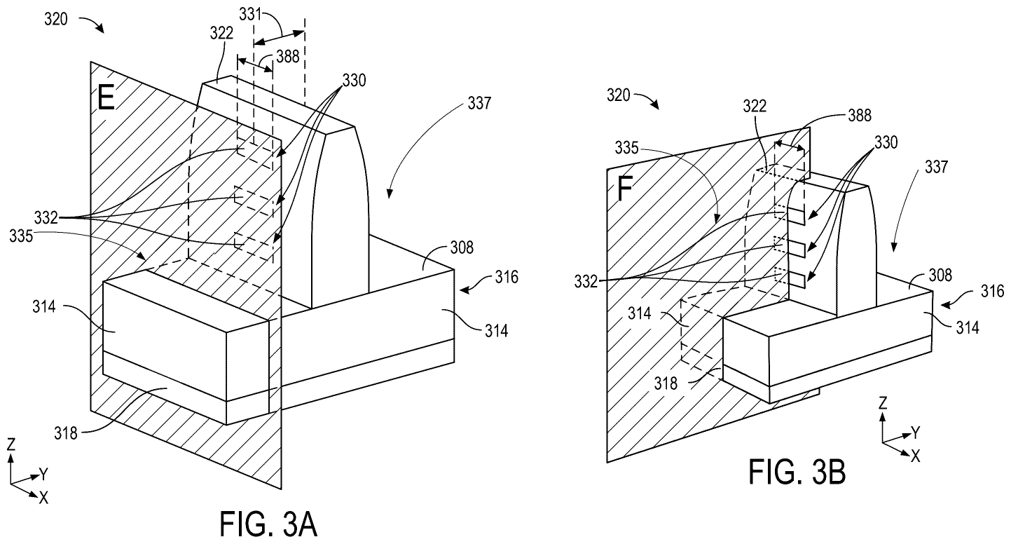

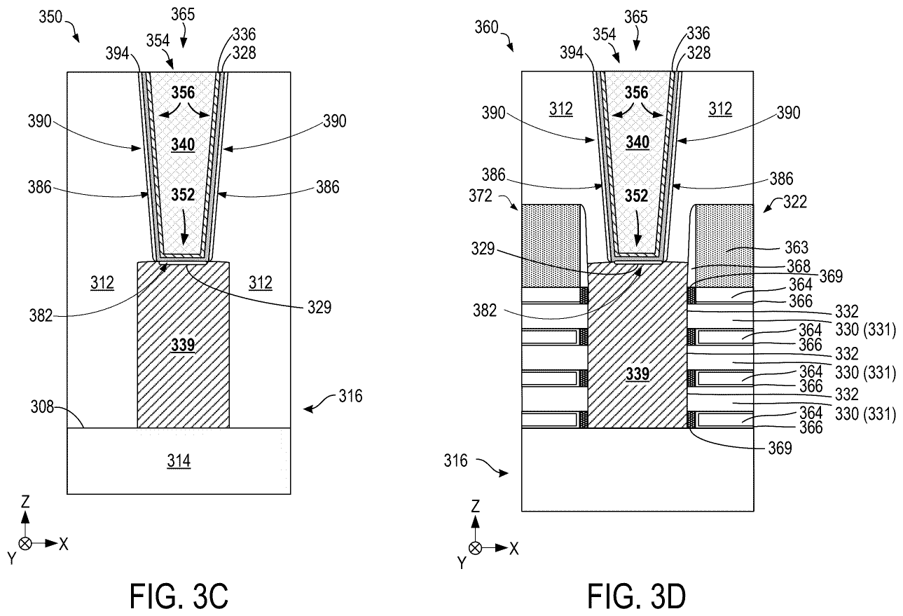

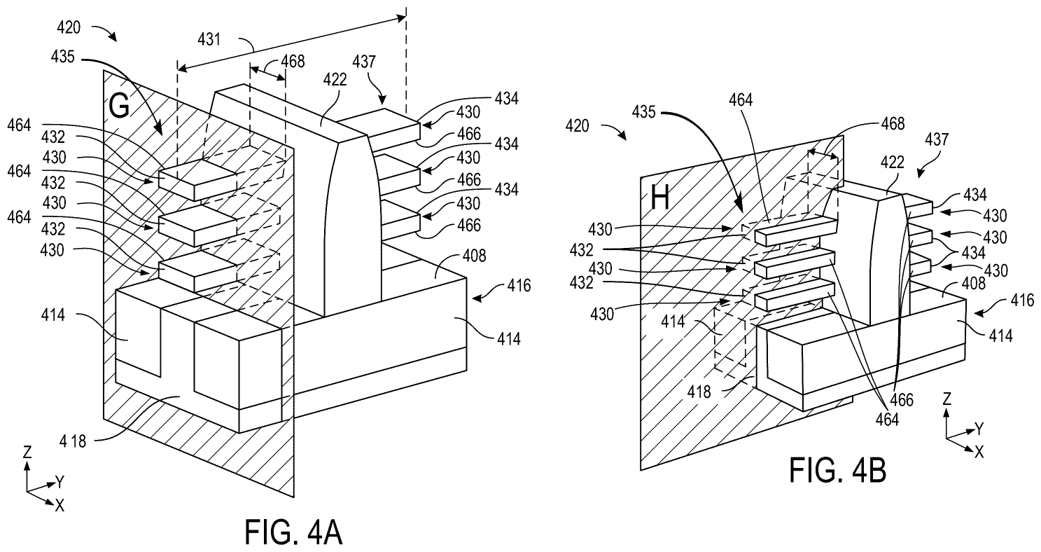

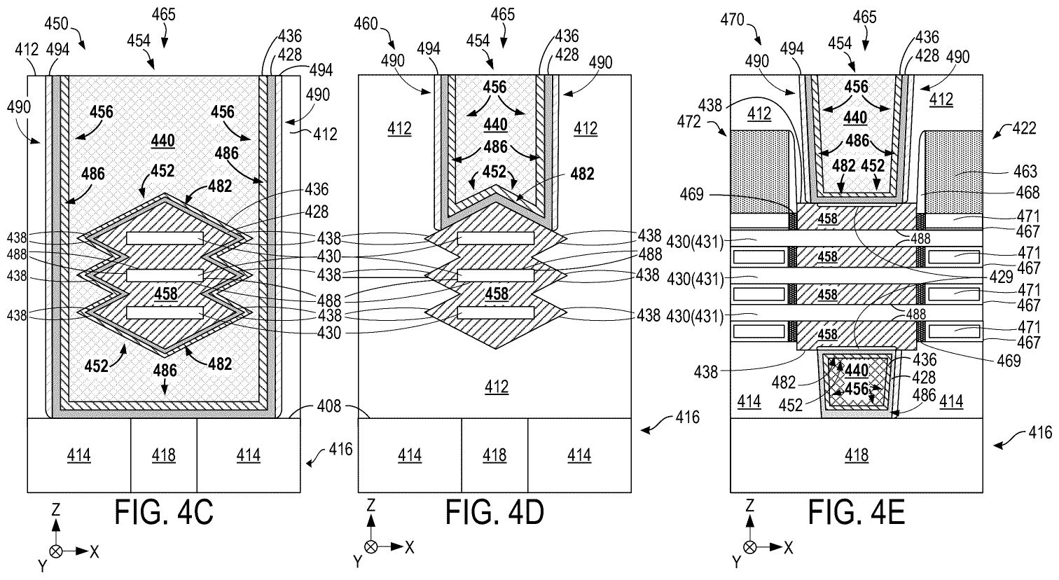

The sidewall portions of a diffusion barrier layer and/or a contact metal layer of any contact described herein can be located on a dielectric layer (such as dielectric layer 112 as illustrated in FIGS. 1C-1D) or on other structures, such as gate spacers or etch barriers. In some embodiments, such as those illustrated in FIGS. 1C-1D and 2C-2E, the sidewall portions of a contact metal layer and a diffusion barrier layer may extend along only a portion of the sidewalls of a contact hole. For example, with reference to FIGS. 1C and 1D, sidewall portions 156 of the contact metal layer 136 and sidewall portions 186 of the diffusion barrier layer 128 extend less than halfway up the sidewalls 190 of the contact hole 162 from the bottom of the contact hole 162. In other embodiments, such as those illustrated in FIGS. 3C-3D and 4C-4E, the sidewall portions of the contact metal layer and the diffusion barrier layer can extend substantially the full length of the contact sidewalls. For example, with reference to FIGS. 3C-3D, sidewall portions 356 of the contact metal layer 336 and sidewall portions 386 of the diffusion barrier layer 328 extend the full length of the sidewalls 390 of the contact hole 162 from the bottom of the contact hole 365.

The cross-sectional views 150 and 160 further comprise a directional etch stop layer 194 along the sidewalls 190 and positioned adjacent to the dielectric layer 112. The layer 194 can be formed on the sidewalls 190 and the bottom of the contact hole 162 prior to formation of the diffusion barrier layer 128 and contact metal layer 136. The layer 194, along with similar layers described herein (e.g., layer 294, 394) can protect the dielectric layer (e.g., 112) in which contact holes are formed from subsequent processing steps that clean the semiconductor surface prior to formation of the diffusion barrier and contact metal layers. These processing steps can comprise directional etches that remove a bottom portion of the directional etch stop layer positioned adjacent to the surface of the semiconductor region (e.g., 104) while preserving all or a portion of the sidewall portions of the directional etch stop layer (e.g., the portions of layer 194 that are illustrated in views 150 and 160). In some embodiments, such directional etch stop layers can comprise silicon nitride (e.g., SixNy, a material comprising silicon and nitrogen). In other embodiments, the directional etch stop layers can comprise other materials. In still other embodiments, a directional etch stop layer is not used during metal contact formation and the portion of a diffusion barrier layer that extends along the sidewalls of a contact hole is positioned adjacent to the dielectric layer (e.g., portion 186 of layer 128 is positioned adjacent to layer 112).

The gate 102 comprises a gate electrode 164, a gate dielectric layer 166, and a gate spacer 168. The gate spacer 168 isolates the gate stack (e.g., gate electrode 164, gate dielectric layer 166) from adjacent features.

In some embodiments, a silicide layer 129 is located in a portion of the source region 104 positioned adjacent to the diffusion barrier layer 128 after fabrication of an integrated circuit die that includes contact 154 is complete. The silicide layer 129 can be formed due to the diffusion of metal from the contact metal layer 136 to the source region 104. As the presence of the diffusion barrier layer 128 can limit or prevent metal diffusion from the contact metal layer 136 to the source region 104, the thickness of the silicide layer 129 can be less than in embodiments where a contact does not have a diffusion barrier layer. In some embodiments, the diffusion barrier layer may be an effective enough barrier to prevent contact metal from diffusing into the source/drain region such that no silicide layer comprising the contact metal is formed at the surface of the source/drain region.

The planar transistor 100, as well as any other transistor comprising source/drain regions to which metal contacts comprising diffusion barrier layers contact can be an n-type or p-type transistor. As mentioned above, a metal contact contacting an n-type source/drain region can be referred to as an n-type contact and a metal contact contacting a p-type source/drain region can be referred to as a p-type contact. An n-type contact can comprise a contact metal layer and diffusion barrier layer that comprise materials that are different from the materials that make up the contact metal layer and diffusion barrier layer in a p-type contact. In some embodiments, the contact metal layers in n-type contacts and p-type contacts can comprise the same materials or comprise metal compounds that have the same metal by elemental composition (e.g., both comprise titanium, both comprise molybdenum). Contact metal layer and diffusion barrier layer materials are described in greater detail below.

FIGS. 2A-2B are simplified perspective views of an example FinFET comprising source/drain contacts with a diffusion barrier layer. FinFET 220 comprises a gate 222, a source region 235, a drain region 237, and a fin 230. The transistor 220 is formed on a substrate 216 comprising a surface 208, a bulk region 218, and isolation regions 214. FIGS. 2C-2D are cross-sectional views of the FinFET 220 taken along plane C of FIG. 2A. Plane C cuts across the source region 235 of FinFET 220. FIG. 2E is a cross-sectional view of the FinFET 220 taken along plane D of FIG. 2B. Plane D extends along the source region 235 of transistor 220 in a direction perpendicular to that of plane C.

The gate 222 controls the flow of current from a source portion 224 of the fin 230 to a drain portion 226 of the fin 230. The channel region of the transistor 220 is formed by the gate 222 encompassing a portion of the fin 230. The gate 222 comprises a gate electrode 264, a gate dielectric layer 266, and a gate spacer 268. The gate spacer 268 isolates the gate stack (e.g., gate electrode 264, gate dielectric layer 266) from adjacent features.

The fin 230 extends upwards from the substrate 216 and extends along a length 231 of the surface 208 from a first end 232 to a second end 234. The source portion 224 of the fin 230 extends along the source region 235 and the drain portion 226 extends along the drain region 237. The source region 235 is shown in FIG. 2E as being located between gate 222 and a second gate 272 of a second FinFET. The second gate 272 is not illustrated in FIGS. 2A-2B for ease of illustration. FIG. 2E illustrates that a fin of one FinFET can be used as a fin in adjacent FinFETs (e.g., fin 230 is used in transistor 220 and the adjacent transistor comprising the second gate 272).

Cross-sectional views 260 and 270 illustrate a semiconductor region 258 positioned adjacent to the portion of the fin 230 extending past the surface 208 of the substrate 216. The semiconductor region 258 can aid in the formation of low resistance source/drain contacts by, for example, providing more source/drain surface area upon which a metal contact can be formed. The semiconductor region 258 is illustrated as encompassing the portion of the fin 230 extending past the surface 208. That is, the semiconductor region 258 encompasses outer surfaces 288 of the fin 230, the outer surface 288 comprising the surfaces of the portion 283 of the fin 230 that extends past the surface 208. In other embodiments, the semiconductor region 258 encompasses less than all of the outer surfaces 288 of the portion 283 of the fin 230. Further, the semiconductor region 258 can extend in a direction along the length 231 of the fin 230 the entire length of the source portion 224 of the fin 230 (as illustrated in FIG. 2E) or along a portion of the length of the source portion 224 of fin 230.

The semiconductor region 258 can be grown epitaxially with in situ doping of one or more n-type dopants (e.g., arsenic, phosphorous, antimony). In source/drain regions of p-type transistors, the semiconductor regions can be epitaxially grown with in situ doping of one or more p-type dopants (e.g., boron, gallium, or aluminum). As used herein, the term “fin” can refer to either a fin with or without a semiconductor region positioned adjacent to the fin (e.g., 258). For example, the term “fin” can refer to either fin 230 or the combined structure of fin 230 plus the semiconductor region 258. In some embodiments, a contact is formed on a fin with no semiconductor region positioned between the contact and the fin. For example, in some embodiments, with reference to FIGS. 2C-2E, diffusion barrier layer 228 can be positioned adjacent to the fin 230.

Cross-sectional views 260, 270, and 280 illustrate a contact 254 contacting the semiconductor region 258. The contact 254 is not shown in FIGS. 2A-2B for ease of illustration. The contact 254 is positioned within a hole 262 in a dielectric layer 212. The contact 254 comprises a diffusion barrier layer 228, a contact metal layer 236, and a fill metal layer 240. The dielectric layer 212 isolates the contact 254 from adjacent contact and/or other features.

A portion 252 of the contact metal layer 236 is located on the semiconductor region 258 and portions 256 of the contact metal layer 236 are not located on the semiconductor region 258. A portion 282 of the diffusion barrier layer 228 is positioned adjacent to the semiconductor region 258 and portions 286 of the diffusion barrier layer 228 are not positioned adjacent to the semiconductor region 258.

The contact metal layer 236 is positioned adjacent to the diffusion barrier layer 228 along at least a portion of the diffusion barrier layer 228 and is positioned adjacent to the fill layer 240. The fill metal layer 240 at least partially fills the hole 262. The contact hole 262 comprises sidewalls 290. The cross-sectional views 260, 270, and 280 further comprise a directional etch stop layer 294 that can have the function and composition of the directional etch stop layer 194 described above.

FIG. 2C illustrates an embodiment in which the contact 254 encompasses the outer surface 238 of the semiconductor region 258. In such embodiments, the contact 254 in FIG. 2C can be referred to as a wrap-around contact. FIG. 2D illustrates an embodiment in which the contact 254 encompasses less than all of the outer surface 238 of the semiconductor region 258.

In some embodiments, a silicide layer 229 is located in a portion of the semiconductor region 258 (or the fin 230 if there is no semiconductor region 258) positioned adjacent to the diffusion barrier layer 228. The silicide layer 229 can be formed in the same manner as silicide layer 129, as described above.

The FinFET 220 is non-planar in that the fin 230 extends upwards from the surface 208 of the substrate 216. As the gate 222 of the FinFET 220 encompasses three sides of a fin, FinFET 220 can be considered a tri-gate transistor. FIGS. 2A-2E illustrate a gate comprising one fin, but the gate of a FinFET can comprise multiple fins in other embodiments.

FIGS. 3A-3B are simplified perspective views of a first example GAAFET comprising source/drain contacts with a diffusion barrier layer. GAAFET 320 comprises a gate 322, a source region 335, a drain region 337, and semiconductor layers 330. The semiconductor layers 330 extend through the gate 322 from the source region 335 to the drain region 337. The transistor 320 is formed on a substrate 316 comprising a surface 308, a bulk region 318, and isolation region 314. FIG. 3C is a cross-sectional view of the GAAFET 320 taken along plane E of FIG. 3A. Plane E cuts across the source region 335 of transistor 320. FIG. 3D is a cross-sectional view of the GAAFET 320 taken along plane F of FIG. 3B. Plane F extends along the source region 335 of transistor 320 in a direction perpendicular to that of plane E. The gate 322 controls the flow of current from the source region 335 to the drain region 337. Channel regions 331 of the transistor 320 are formed by the gate 322 encompassing the semiconductor layers 330. The semiconductor layers 330 are located above and separate from the substrate 316, are stacked vertically with respect to the substrate, and are substantially parallel to the surface 308 of the substrate 316.

The source region 335 comprises a source semiconductor region (or layer) 339 (shown in FIGS. 3C-3D, but not FIGS. 3A-3B) positioned laterally adjacent to ends 332 of the semiconductor layers 330 and positioned adjacent to the surface 308 of the substrate 316. FIG. 3D illustrates the source semiconductor region 339 positioned between gate 322 and a gate 372 of a second GAAFET (not shown in FIGS. 3A-3B, for ease of illustration). The drain region 337 comprises a drain semiconductor region (not shown in FIGS. 3A-3B) positioned laterally adjacent to ends of the semiconductor layers 330 that are opposite the ends 332. The drain semiconductor region is further positioned adjacent to the surface 308 of the substrate 316.

The gate 322 controls the flow of current from the source region 335 to the drain region 337 via channel regions 331 of transistor 320. The channel regions 331 are created by the gate 322 encompassing the semiconductor layers 330. The gate 322 comprises a gate electrode 363, gate metal layers 364, gate dielectric layers 366, a gate spacer 368, and cavity spacers 369. The gate spacer 368 and cavity spacers 369 isolate the gate stack (e.g., gate electrode 363, gate metal layers 364, and gate dielectric layers 366) from adjacent features. The semiconductor layers 330 are positioned between adjacent gate metal layers 364 and a gate dielectric layer 366 is positioned between a semiconductor layer 330 and a gate metal layer 364.

In the GAAFET embodiment illustrated in FIGS. 3A-3B, the semiconductor layers 330 do not extend into the source and drain regions 335 and 337. Rather, the source semiconductor region 339 and drain semiconductor region act as the source/drain semiconductor regions for the transistor 320. In other embodiments, the semiconductor layers that extend through the gate of a GAAFET further extend into the source and drain regions and source and drain semiconductor regions encompass the semiconductor layers (e.g., FIGS. 4A-4E). In some embodiments, the source semiconductor region 339 and the drain semiconductor region are epitaxially grown on the surface 308 of the substrate 316. Epitaxially-grown source semiconductor region 339 and the drain semiconductor region can be grown epitaxially with in situ doping of one or more n-type dopants (e.g., arsenic, phosphorous). Semiconductor regions epitaxially grown in source/drain regions of p-type transistors can be grown with in situ doping of one or more p-type dopants (e.g., boron, gallium, or aluminum).

Cross-sectional views 350 and 360 illustrate a contact 354 contacting the source semiconductor region 339. The contact 354 is not shown in FIGS. 3A-3B for ease of illustration. The contact 354 is positioned within a hole 365 in dielectric layer 312. The contact 354 comprises a diffusion barrier layer 328, a contact metal layer 336, and a fill metal layer 340. The contact metal layer 336 is positioned adjacent to the diffusion barrier layer 328. The fill metal layer 340 at least partially fills the hole 365. The contact hole 365 comprises sidewalls 390. The cross-sectional views 350 and 360 further comprise a directional etch stop layer 394 that has the function and composition of directional etch stop layer 194 described above. In other embodiments, a directional etch stop layer is not used during metal contact formation and the portion of a diffusion barrier layer that extends along the sidewalls of a contact hole is positioned adjacent to a dielectric layer (e.g., layer 312). The dielectric layer 312 isolates the contact 354 from adjacent contacts and/or other features.

A portion (bottom portion) 352 of the contact metal layer 328 is located on the source semiconductor region 339 and portions 356 (sidewall portions) of contact metal layer 328 are not located on the source semiconductor region 339. In some embodiments, the portions 356 are substantially perpendicular to the portion 352. A portion 382 of the diffusion barrier layer 328 is positioned adjacent to the semiconductor region 339 and portions 386 of the diffusion barrier layer 328 are not positioned adjacent to the semiconductor region 339.

In some embodiments, a silicide layer 329 is located in a portion of the source semiconductor region 339 positioned adjacent to the diffusion barrier layer 328 after processing is complete. The silicide layer 329 can be formed in the same manner as silicide layer 129, as described above.

FIGS. 4A-4B are simplified perspective views of a second example GAAFET comprising source/drain contacts with a diffusion barrier layer. GAAFET 420 comprises a gate 422, a source region 435, a drain region 437, and semiconductor layers 430. The individual semiconductor layers 430 are located above and separate from the substrate 416, are substantially parallel to the surface 408 of the substrate 416 and extend along a length 431 from a first end 432 of the individual semiconductor layers 430 to a second end 434 of the individual semiconductor layers 430. The semiconductor layers 430 are stacked vertically with respect to the surface 408 of the substrate 416. The transistor 420 is formed on a substrate 416 comprising a surface 408, a bulk region 418, and isolation regions 414. FIGS. 4C-4D are cross-sectional views of the GAAFET 420 taken along plane G of FIG. 4A. Plane G cuts across the source region 435 of GAAFET 420. FIG. 4E is a cross-sectional view of the GAAFET 420 taken along plane H of FIG. 4B. Plane H extends along the source region 435 of transistor 420 in a direction perpendicular to that of plane G.

The gate 422 controls the flow of current through multiple channel regions 431 from source portions 464 of the semiconductor layers 430 to drain portions 466 of the semiconductor layers 430. Channel regions 431 of the transistor 420 are formed by the gate 422 encompassing a portion of the individual semiconductor layers 430.

The source region 435 comprises a source semiconductor region 458 (shown in FIGS. 4C-4E, but not FIGS. 4A-4B) positioned adjacent to the source portions 464 of the semiconductor layers 430. FIG. 4E illustrates the semiconductor layers 430 and the source semiconductor region 458 positioned between gate 422 and a gate 472 of a second GAAFET (not shown in FIGS. 4A-4B). The drain region 437 comprises drain portions 466 of the semiconductor layers 430 and a drain semiconductor region is positioned adjacent to and encompasses at least a portion of the length 431 of the drain portions 466 of the semiconductor layers 430.

The gate 422 comprises a gate electrode 463, gate metal layers 471, gate dielectric layers 467, a gate spacer 468, and cavity spacers 469. The gate spacer 468 and cavity spacers 469 isolate the gate stack (e.g., gate electrode 463, gate metal layers 471, and gate dielectric layers 467) from adjacent features. The channel portions 431 of the semiconductor layers 430 are positioned between adjacent gate metal layers 471 and a gate dielectric layer 467 is positioned between a semiconductor layer 430 and a gate metal layer 471.

Cross-sectional views 450, 460, and 470 illustrate a semiconductor region 458 positioned adjacent to the source portions 464 of the semiconductor layers 430. The source semiconductor region 458 can aid in the formation of low resistance source/drain contacts by, for example, providing more source/drain surface area upon which a metal contact can be formed. The source semiconductor region 458 is illustrated as encompassing the source portions 464 of the semiconductor layers 430. That is, the source semiconductor region 458 encompasses the top, bottom, and side surfaces 488 of the semiconductor layers 430 (as viewed in the cross-sectional views 4C-4D). Further, the semiconductor region 458 can extend along all (as illustrated in FIG. 4E) or a portion of the source portions 464 of the semiconductor layers 430. The semiconductor region 458 can be grown epitaxially with in situ doping of one or more n-type dopants (e.g., arsenic, phosphorous, antimony). Semiconductor regions grown epitaxially in source/drain regions of p-type transistors can be grown with in situ doping of one or more p-type dopants (e.g., boron, gallium, aluminum).

Cross-sectional views 450, 460, and 470 further illustrate a contact 454 contacting the source semiconductor region 458. The contact 454 is not shown in FIGS. 4A-4B for ease of illustration. The contact 454 is positioned adjacent to dielectric layer portions 412. The contact 454 comprises a diffusion barrier layer 428, a contact metal layer 436, and a fill metal layer 440. The contact metal layer 436 is positioned adjacent to the diffusion barrier layer 328. The diffusion barrier layer 428 and the contact metal layer 436 layer are positioned within a contact hole (or cavity) 465 in the dielectric layer 412 and the fill metal layer 440 at least partially fills the hole 465. The contact hole 465 comprises sidewalls 490. The cross-sectional views 350 and 360 further comprise a directional etch stop layer 394 that has the function and composition of directional etch stop layer 194 described above. In other embodiments, a directional etch stop layer is not used during metal contact formation and the portion of a diffusion barrier layer that extends along the sidewalls of a contact hole is positioned adjacent to a dielectric layer (e.g., layer 312). The dielectric layer 412 isolates the contact 454 from adjacent contacts and other features.

A portion 452 of the contact metal layer 436 is located on the source semiconductor region 458 and a portion 456 of contact metal layer 436 is not located on the source semiconductor region 458. As shown in FIGS. 4C, the contact metal layer 436 can comprise portions that are physically separate from each other (e.g., 452, 456). A portion 482 of the diffusion barrier layer 428 is positioned adjacent to the source semiconductor region 458 and a portion 486 of diffusion barrier layer 428 is not positioned adjacent to the source semiconductor region 458.

FIGS. 4C and 4E illustrate an embodiment in which the contact 454 encompasses outer surfaces 438 of the semiconductor region 458. As such, the contact 454 in FIGS. 4C and 4E can be referred to as wrap-around contacts. FIG. 4D illustrates an embodiment in which the contact 454 encompasses a portion of the outer surfaces 438 of the source semiconductor layer 458.

In some embodiments, a silicide layer 429 is located in a portion of the semiconductor region 458 positioned adjacent to the diffusion barrier layer 428 after completion of processing. The silicide layer 429 can be formed in the same manner as silicide layer 129, as described above. For ease of illustration, the silicide layer 429 is only shown in the cross-sectional view of FIG. 4E.

The GAAFET transistors 320 and 420 are non-planar in that the semiconductor layers (330, 430) are located above and are separate from the substrate (316, 416). The transistors 320 and 420 are considered gate-all-around transistors as the gate (322, 422) encompasses the channel portions (331, 431) of the semiconductor layers (430, 430).

GAAFETs can be alternatively referred to as nanowire or nanosheet (nanoribbon) transistors, depending on the width (e.g., 368, 468) of the semiconductor layer (e.g., 330, 430) extending through the gate (e.g., 322, 422) relative to the thickness of the semiconductor layer. For example, as the width 388 of the semiconductor layers 330 in FIGS. 3A-3B is greater than the thicknesses of the semiconductor layers 330, GAAFET 320 can be referred to as a nanosheet or nanoribbon transistor. GAAFETs in which the widths and thicknesses of the semiconductor layers are similar can be referred to as nanowire transistors.

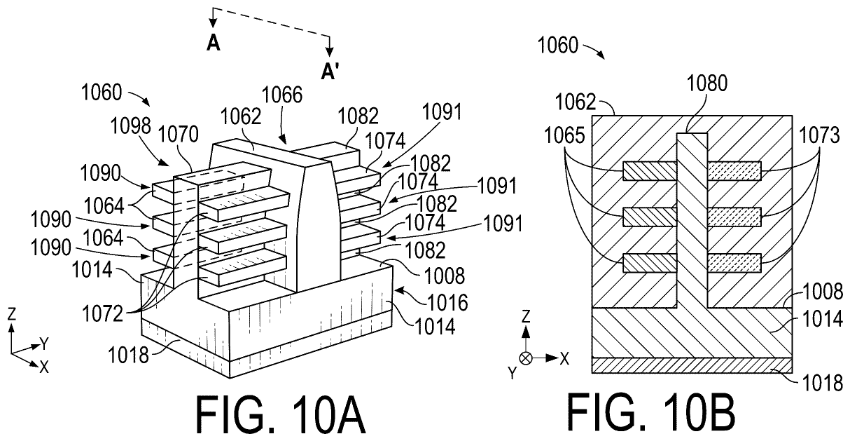

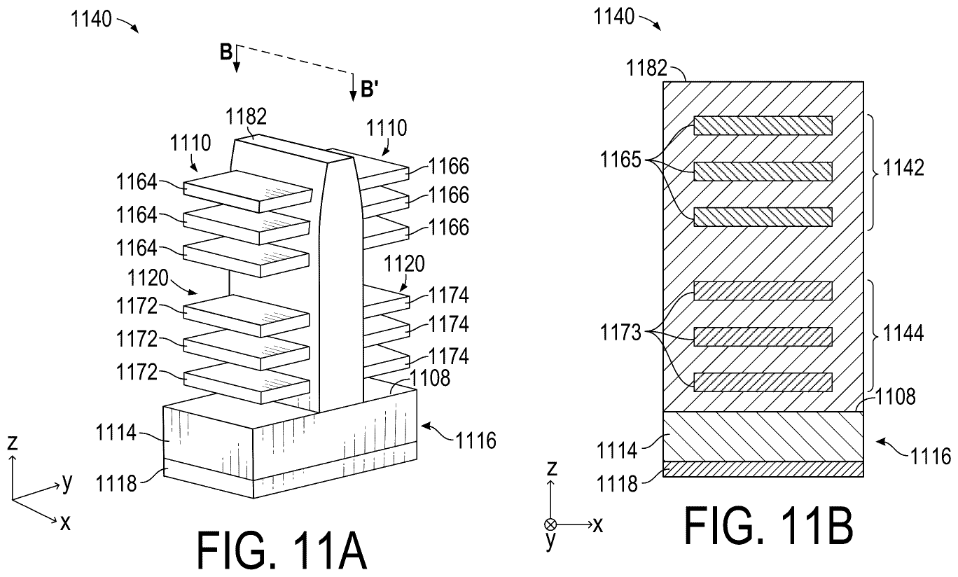

Metal contacts with diffusion barrier layers can be used in other transistor architectures comprising GAAFETs, such as in complementary FET (CFETs) transistor architectures, as illustrated in FIGS. 11A-11B. In such embodiments, as discussed in greater detail below, p-type and n-type GAAFETs are stacked vertically. Metal contacts with diffusion barrier layers can also be used in forksheet transistor architectures, such as illustrated in FIGS. 10A-10B. In forksheet transistors, the diffusion barrier layers wrap around three sides of the semiconductor layers (e.g., 1064, 1076), in the n-type and p-type source/drain regions with the fourth side of the semiconductor layers positioned adjacent to an isolation region (1070) that separates the p-type source/drain regions from the n-type source/drain regions (1064).

FIGS. 5A-5H illustrate an example simplified process sequence for forming n-type and p-type contacts comprising a diffusion barrier layer. FIG. 5A illustrates a structure 500 comprising fins 530 and 531 extending from a surface 508 of a substrate 516 comprising a bulk region 518 and isolation regions 514. FIG. 5B illustrates the structure 500 after formation of epitaxially-grown semiconductor regions 558 and 559 positioned adjacent to the portions of fins 530 and 531 extending beyond the surface 508, respectively. The semiconductor regions 558 and 559 are doped n-type and p-type, respectively. The semiconductor region 558 can be epitaxially grown with in situ doping of one or more n-type dopants and the semiconductor region 559 can be epitaxially grown with in situ doping of one or more p-type dopants. FIG. 5C illustrates the structure 500 after the formation of a dielectric layer 512 and removal (e.g., by etching) of portions of the dielectric layer 512 to form contact holes 565 and 566. Removal of portions of the dielectric layer 512 exposes the n-type semiconductor region 558 and the p-type semiconductor region 559.

FIG. 5D illustrates the structure 500 after formation of a diffusion barrier layer 528 in contact hole 565. Prior to formation of the diffusion barrier layer 528, a mask layer 570 is formed that fills in and covers contact hole 566 to prevent formation of diffusion barrier layer 528 in the contact hole 566. A first portion 552 of the diffusion barrier layer 528 is positioned adjacent to the n-type semiconductor region 558 and second portions 556 of the diffusion barrier layer 528 are positioned adjacent to sidewalls 590 of the contact hole 565. The diffusion barrier layer 528 comprises a material that has a suitable work function to enable a low resistance contact to the n-type semiconductor region 558. FIG. 5E illustrates the structure 500 after formation of a metal contact layer 536 positioned adjacent to the diffusion barrier layer 528. A first portion 582 of the metal contact layer 536 is located on the n-type semiconductor region 558 and second portions 586 of the metal contact layer 536 are located on sidewalls 590 of the contact hole 565.

FIG. 5F illustrates the structure 500 after formation of a diffusion barrier layer 529 in contact hole 566. Prior to formation of the diffusion barrier layer 529, the mask layer 570 is removed and a mask layer 572 is formed to fill in and cover contact hole 565 to prevent formation of diffusion barrier layer 529 in the contact hole 565. A first portion 553 of the diffusion barrier layer 529 is positioned adjacent to the p-type semiconductor region 559 and second portions 557 of the diffusion barrier layer 529 are positioned adjacent to sidewalls 591 of the contact hole 566. The diffusion barrier layer 529 comprises a material that has a suitable work function to enable a low resistance contact to the p-type semiconductor region 559. FIG. 5G illustrates the structure 500 after formation of a metal contact layer 537 positioned adjacent to the diffusion barrier layer 529. A first portion 583 of the metal contact layer 537 is located on the n-type semiconductor region 559 and second portions 587 of the metal contact layer 537 are located on sidewalls 591 of the contact hole 566. FIG. 5H illustrates the structure 500 after filling the contact holes 565 and 565 with fill metal layers 540 and 541. Mask layer 572 is removed prior to the filling of the holes 565 and 566 with the fill metal. Fill metal layer 540 at least partially fills contact hole 565 and is located on the metal contact layer 536, and fill metal layer 541 at least partially fills contact hole 566 and is located on the metal contact layer 537.

The diffusion barrier layer, metal contact layer, and fill metal layers of the contacts described herein can be formed by any thin layer formation process, such as chemical vapor deposition (CVD), plasma-enhanced chemical vapor deposition (PECVD), physical vapor deposition (e.g., such as sputtering), or another suitable deposition process. In some embodiments, the contact formation process illustrated in FIGS. 5A-5H can comprise additional steps, such as forming an etch stop layer after forming the contact hole 565 to protect the dielectric layer 512 from being etched during processing steps that prepare the surface of the semiconductor region 558 before formation of the diffusion barrier layer and contact layers on the semiconductor region 558.

The various layers, regions, contacts, transistors, and other structures described or referenced herein can comprise various materials as follows. The bulk region of a substrate upon which transistors are fabricated and to which a contact comprising a diffusion barrier layer can contact (e.g., substrate 116, 216, 316, 416, 516) can comprise a semiconductor comprising silicon (e.g., bulk silicon, silicon-on-insulator (e.g., bulk silicon with a buried silicon dioxide layer)), silicon and germanium (e.g., SiGe), any other suitable semiconductor described or referenced herein, or any other suitable semiconductor.

A source or drain region of an n-type field effect transistor can comprise one or more n-type dopants, such as phosphorous, arsenic, antimony, lithium, bismuth, or tellurium. A source or drain region of a p-type field effect transistor can comprise one or more p-type dopants, such as boron, gallium, indium, or aluminum.

A fin (e.g., 230, 530) of a FinFET, a source or drain semiconductor region (e.g., 104, 258, 339, 458, 558), or any of the semiconductor layers (e.g., 330, 430) positioned above the substrate and forming the channel regions of a GAAFET (GAAFET semiconductor layer) can comprise silicon, silicon and germanium, or another suitable semiconductor. A fin or a GAAFET semiconductor layer that is part of an n-type transistor can comprise one or more n-type dopants, such as phosphorous, arsenic, antimony, or another suitable n-type dopant. A fin or a GAAFET semiconductor layer that is part of a p-type transistor can comprise one or more p-type dopants, such as boron, gallium, aluminum, or another suitable p-type dopant. A fin or GAAFET semiconductor layer can comprise one or more different n-type dopants or one or more p-type dopants in different portions of the fin or GAAFET semiconductor layer. For example, the channel region of a fin or GAAFET semiconductor layer can comprise one or more different dopants than source portions or drain portions of the fin or GAAFET semiconductor layer.

In some embodiments, a source or drain semiconductor region to which a metal contact can contact (e.g., 104, 258, 339, 458, 558) can be epitaxially grown. N-type or p-type dopants can be introduced into these semiconductor regions via in situ doping during epitaxial growth of these source or drain semiconductor regions.

The diffusion barrier layer (e.g., layer 128, 228, 328, 428, 528) in n-type contacts can comprise carbon; titanium carbide (TiC, a material comprising titanium and carbon); TiAlC, a material comprising titanium, aluminum, and carbon; titanium phosphide (TiP, a material comprising titanium and phosphorous); titanium nitride (TiN, a material comprising titanium and nitrogen); titanium carbo-nitride (TiCN, a material comprising titanium, carbon, and nitrogen); titanium boride (e.g., TiB, a material comprising titanium and boron); AlC, a material comprising aluminum and carbon; aluminum nitride (AlN, a material comprising aluminum and nitrogen); or other suitable material.

The contact metal layer (e.g., layer 136, 236, 336, 436, 536) in n-type contacts can comprise titanium; titanium aluminide (TiAl, a material comprising titanium and aluminum); aluminum; scandium; erbium; yttrium; ytterbium; dysprosium; TiAlC, a material comprising titanium, aluminum, and carbon; magnesium; magnesium aluminide (MgAl, a material comprising magnesium and aluminum); or other suitable material.

The diffusion barrier layer in p-type contacts can comprise carbon; titanium carbide (TiC, a material comprising titanium and carbon); TiAlC, a material comprising titanium, aluminum, and carbon; titanium phosphide (TiP, a material comprising titanium and phosphorous); molybdenum boride (MoB, a material comprising molybdenum and boron); titanium carbo-nitride (TiCN, a material comprising titanium, carbon, and nitrogen); titanium boride (e.g., TiB, a material comprising titanium and boron); AlC, a material comprising aluminum and carbon; aluminum nitride (AlN, a material comprising aluminum and nitrogen); or other suitable material.

The contact metal layer in p-type contacts can comprise titanium, molybdenum, tungsten, cobalt, nickel, platinum, molybdenum boride (MoB), titanium phosphide (TiP), nickel platinum (NiPt, a material comprising nickel and platinum), tantalum, niobium, or other suitable material.

In some embodiments, the n-contact type comprises one of the following diffusion barrier layer-contact metal layer pairs: titanium carbide-titanium (TiC—Ti), titanium carbide-titanium phosphide (TiC—TiP), titanium carbide-TiAlC (TIC-TiAlC), titanium carbide-scandium (TiC—Sc), or carbon-scandium (C—Sc). In some embodiments, the p-contact type comprises one of the following diffusion barrier layer-contact metal layer pairs: titanium carbide-molybdenum (TiC—Mo), titanium carbide-titanium (TiC—Ti), titanium carbide-nickel (TiC—Ni), molybdenum boride-molybdenum (MoB—Mo), or titanium boride-molybdenum (TiB—Mo).

In some embodiments, the material comprising diffusion barrier layer can be selected based in part on the work function of the material. For n-type source/drain regions, this means that the work function of the material comprising the diffusion barrier layer is close to or smaller than the electron affinity of the semiconductor comprising the n-type source/drain region. For a p-type semiconductor, this means that the work function of the material comprising the diffusion barrier layer is close to or larger than the sum of the electron affinity and the bandgap energy of the semiconductor comprising the p-type source/drain region.

In some embodiments, the thickness of a diffusion barrier layer is about 3 nanometers or less. In some embodiments, the thickness of the diffusion barrier layer is in the range of 0.5 to two nanometers. In some embodiments, the thickness of a contact metal layer is in the range of two to ten nanometers.

Although FIGS. 1C-1D, 2C-2E, 3C-3D, and 4C-4E illustrate a contact contacting to source/drain regions of a transistor, the contacts described herein comprising a diffusion barrier layer can contact to any n-type semiconductor region to create a thermally stable low resistance contact.

The fill metal layer in any of the metal contacts disclosed herein can comprise tungsten, cobalt, titanium, gold, aluminum, molybdenum, chromium, nickel, or other suitable metal.

The isolation regions isolating adjacent transistors from each other (e.g., 114, 214, 314, 414, 514) can comprise silicon dioxide (SiO₂, a material comprising silicon and oxide) or any other suitable oxide, nitride, or any other material suitable for providing electrical isolation between adjacent transistors. The isolation regions isolating source contact metals or drain contact metals from the substrate or other contact metals (e.g., 112, 212, 312, 412, 512) can be a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen), or silicon nitride (Si₃N₄, which is a material that comprises silicon and nitrogen).

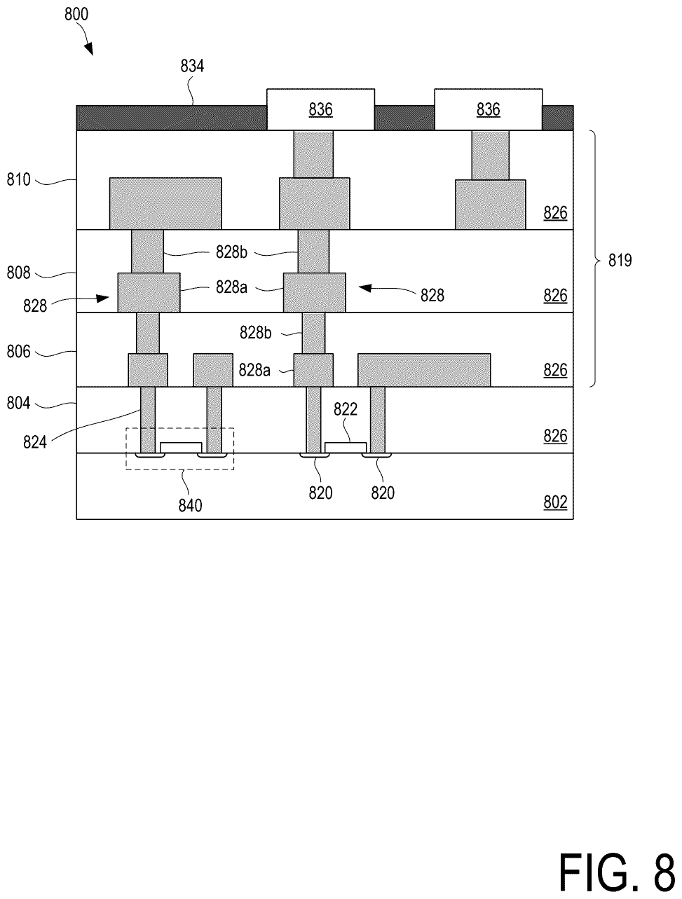

The gate dielectric layers (e.g., 166, 266, 366, 466) of a transistor, can comprise any of the gate dielectric materials discussed below in regard to FIG. 8. The gate electrode layers (e.g., 164, 264, 364, 463) and gate layers (e.g., 364, 471) of a transistor can comprise one or more of the gate electrode materials discussed below in regard to FIG. 8.

The contacts described herein can be included in any integrated circuit die or any microprocessor assembly, integrated circuit component, computing system, computing device, or any other structure that can include an integrated circuit die. An integrated circuit component comprising any of the contacts described herein can be attached to a printed circuit board (motherboard, mainboard). In some embodiments, one or more additional integrated circuit components or other components (e.g., battery, antenna) can be attached to the printed circuit board. In some embodiments, the printed circuit board and the integrated circuit component can be located in a computing device comprising a housing that encloses the printed circuit board and the integrated circuit component.

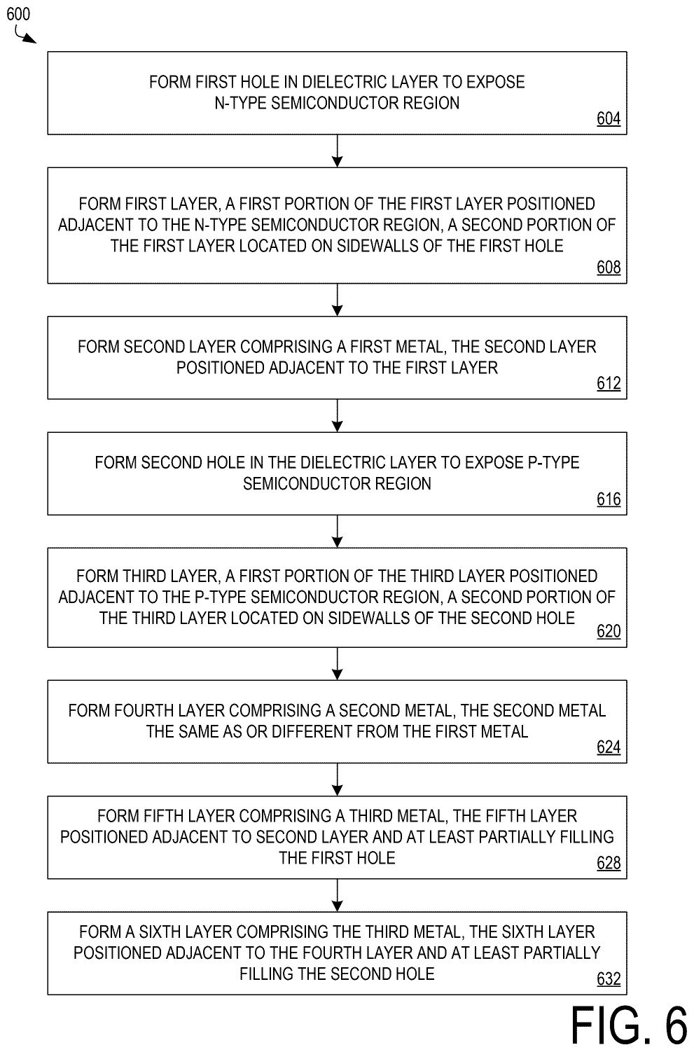

FIG. 6 is an example method of forming metal source/drain contacts comprising diffusion barrier layers. The method 600 can be performed by, for example, an integrated circuit component manufacturer. At 604, forming a first hole is formed in a dielectric layer located on a substrate to expose an n-type semiconductor region comprising a semiconductor and an n-type dopant. At 608, first layer is formed, a first portion of the first layer positioned adjacent to the n-type semiconductor region, a second portion of the first layer located on one or more first sidewalls of the first hole. At 612, a second layer is formed comprising a first metal, the second layer positioned adjacent to the first layer. At 616, a second hole is formed in the dielectric layer to expose a p-type semiconductor region comprising the semiconductor and p-type dopant. At 620, a third layer is formed, a first portion of the third layer positioned adjacent to the p-type semiconductor region, a second portion of the third layer located on one or more second sidewalls of the second hole. At 624, a fourth layer is formed comprising a second metal, an elemental composition of the second metal the same as or different from an elemental composition of the first metal, the second layer positioned adjacent to the third layer. At 628, a fifth layer is formed comprising a third metal, the fifth layer positioned adjacent to at least a portion of the second layer and at least partially filling the first hole. At 632, form a sixth layer is formed comprising the third metal, the sixth layer positioned adjacent to at least a portion of the fourth layer and at least partially filling the second hole.

The method 600 can have more or fewer steps in other embodiments. For example, method 600 can further comprise forming a seventh layer that functions as a directional etch stop and positioned adjacent to the sidewalls of the first contact hole prior to formation of the first layer. In another example, the method 600 can further comprise forming an eighth layer that functions as a directional etch stop and positioned adjacent to the sidewalls of the second contact hole prior to formation of the second layer.

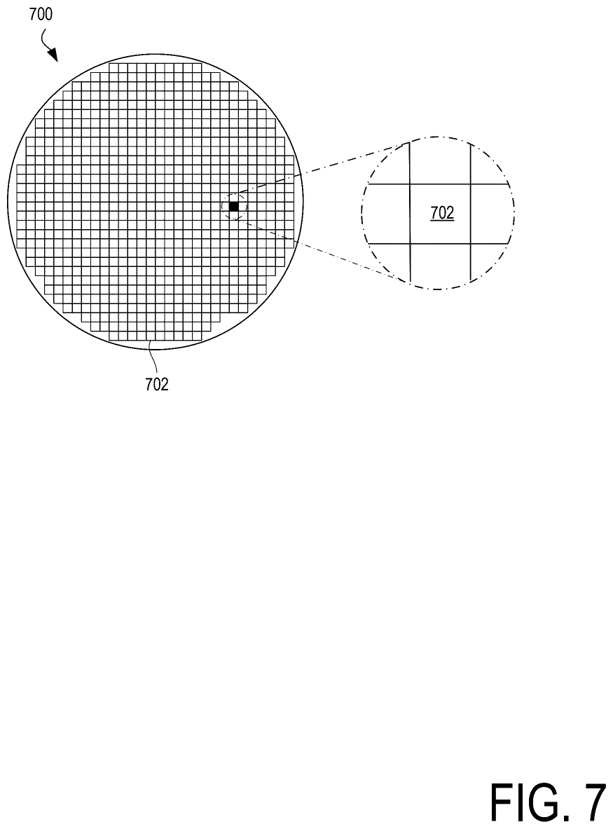

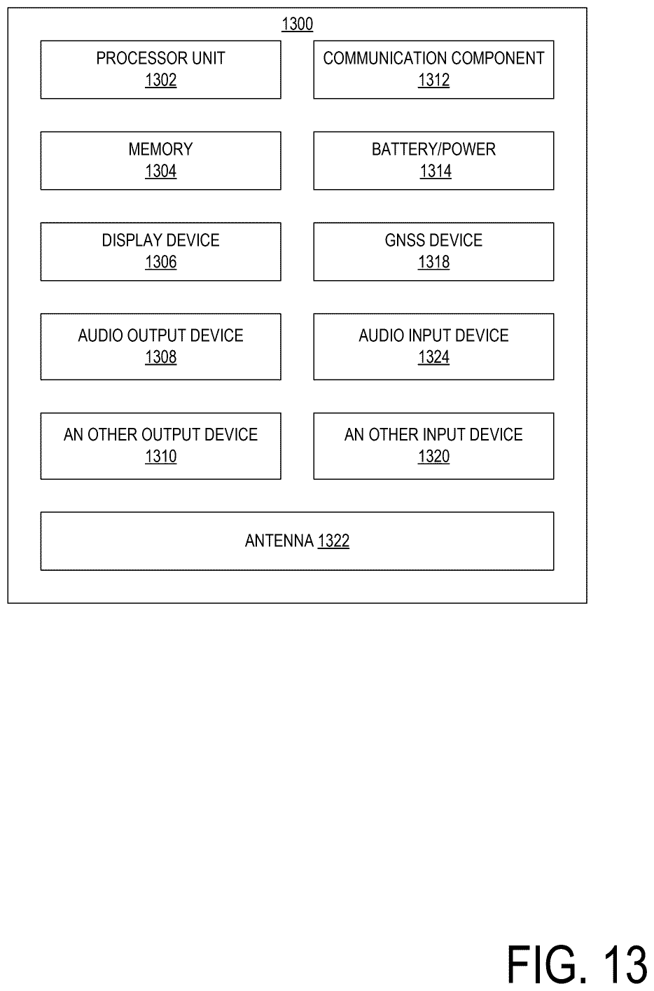

FIG. 7 is a top view of a wafer 700 and dies 702 that may be included in any microprocessor assembly, integrated circuit component, computing system, computing device, or any other structure that can include an integrated circuit die. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The dies 702 may comprise any of the metal contacts comprising diffusion barrier layers disclosed herein. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1302 of FIG. 13) or other logic that is configured to store information in the memory devices or execute instructions stored in the memory array. Various ones of the microelectronic assemblies disclosed herein may be manufactured using a die-to-wafer assembly technique in which some dies are attached to a wafer 700 that include other dies, and the wafer 700 is subsequently singulated.

FIG. 8 is a cross-sectional side view of an integrated circuit device 800 that may be included in any microprocessor assembly, integrated circuit component, computing system, computing device, or any other structure that can include an integrated circuit die. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as 4Enanoribbon, nanosheet, or nanowire transistors.

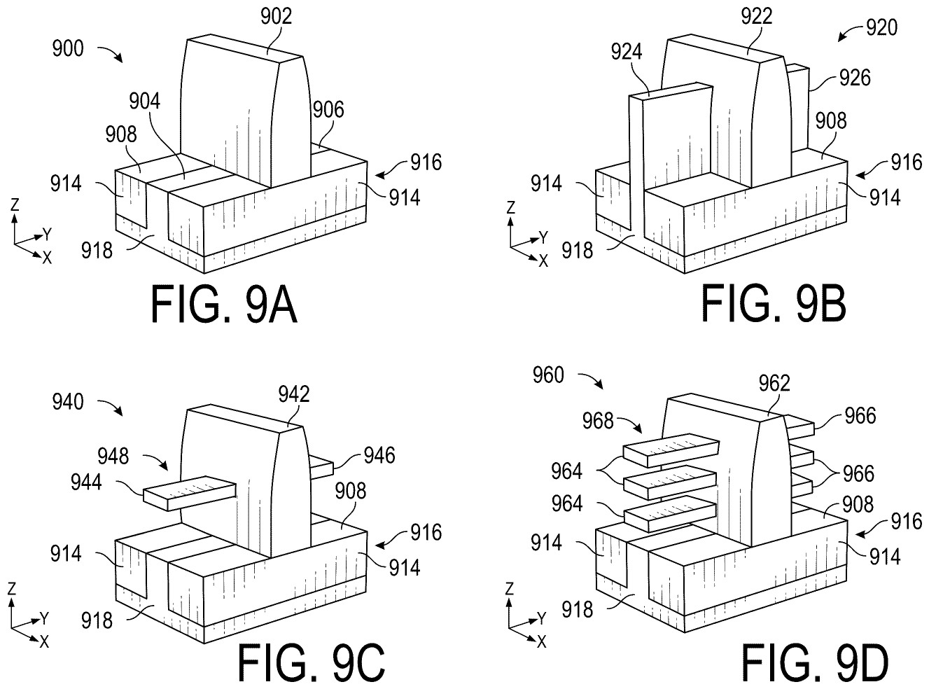

FIGS. 9A-9D are simplified perspective views of example planar, FinFET, gate-all-around, and stacked gate-all-around transistors. The transistors illustrated in FIGS. 9A-9D are formed on a substrate 916 having a surface 908. Isolation regions 914 separate the source and drain regions of the transistors from other transistors and from a bulk region 918 of the substrate 916.

FIG. 9A is a perspective view of an example planar transistor 900 comprising a gate 902 that controls current flow between a source region 904 and a drain region 906. The transistor 900 is planar in that the source region 904 and the drain region 906 are planar with respect to the substrate surface 908.

FIG. 9B is a perspective view of an example FinFET transistor 920 comprising a gate 922 that controls current flow between a source region 924 and a drain region 926. The transistor 920 is non-planar in that the source region 924 and the drain region 926 comprise “fins” that extend upwards from the substrate surface 908. As the gate 922 encompasses three sides of the semiconductor fin that extends from the source region 924 to the drain region 926, the transistor 920 can be considered a tri-gate transistor. FIG. 9B illustrates one S/D fin extending through the gate 922, but multiple S/D fins can extend through the gate of a FinFET transistor.

FIG. 9C is a perspective view of a gate-all-around (GAA) transistor 940 comprising a gate 942 that controls current flow between a source region 944 and a drain region 946. The transistor 940 is non-planar in that the source region 944 and the drain region 946 are elevated from the substrate surface 908.

FIG. 9D is a perspective view of a GAA transistor 960 comprising a gate 962 that controls current flow between multiple elevated source regions 964 and multiple elevated drain regions 966. The transistor 960 is a stacked GAA transistor as the gate controls the flow of current between multiple elevated S/D regions stacked on top of each other. The transistors 940 and 960 are considered gate-all-around transistors as the gates encompass all sides of the semiconductor portions that extends from the source regions to the drain regions. The transistors 940 and 960 can alternatively be referred to as nanowire, nanosheet, or nanoribbon transistors depending on the width (e.g., widths 948 and 968 of transistors 940 and 960, respectively) of the semiconductor portions extending through the gate.

FIGS. 10A and 10B are perspective and cross-sectional views of an example forksheet transistor device. Generally, a forksheet transistor device comprises an n-type stacked GAAFET located next to a p-type stacked GAAFET with a dielectric region separating the nanoribbons (nanosheets, nanowires) forming the source, drain, and channel regions of the two GAAFETs. The forksheet transistor device 1060 is formed on a substrate 1016 having a surface 1008. The n-type and p-type GAAFETs comprise three vertically stacked nanoribbons 1090 and 1091, respectively. Each nanoribbon 1090 of the n-type GAAFET is coplanar with a nanoribbon 1091 of the p-type GAAFET. The substrate 1016 comprises an isolation region 1014 located on top of a bulk region 1018. A dielectric region 1098 separates the nanoribbons 1090 of the n-type GAAFET from the nanoribbons 1091 of the p-type GAAFET. A first portion 1070 of the dielectric region 1098 is positioned between n-type source regions 1064 and p-type source regions 1074, a second portion 1082 of the dielectric region 1098 is located between n-type drain regions 1066 (not viewable in FIG. 10A) and p-type drain regions 1074, and a third portion 1080 of the dielectric region 1098 is located between channel regions 1065 of nanoribbons 1090 and channel regions 1073 of nanoribbons 1091. In some embodiments, the dielectric region 1098 can be an extension of the substrate isolation region 1014. The gate 1062 controls current flow between the n-type source 1064 and drain 1066 regions, and the p-type source 1072 and drain 1074 regions.

FIG. 10B is a cross-sectional view of the gate region of the forksheet transistor device 1060 taken along the line A-A′ of FIG. 10A. Channel regions 1065 connect n-type source regions 1064 to n-type drain regions 1066, channel regions 1073 connect p-type source regions 1072 to p-type drain regions 1074, and the third portion 1080 of the dielectric region 1098 separates the channel regions 1065 from the channel regions 1073 and connects the first portion 1070 of the dielectric region 1098 to the second portion 1082 of the dielectric region 1098. Thus, the forksheet transistor device 1060 comprise an n-type transistor comprising n-type source regions 1064, channel region 1065, n-type drain regions 1066, and gate 1062; and a p-type transistor comprising p-type source regions 1072, channel regions 1073, p-type drain regions 1074, and gate 1062. The gate 1062 is shared by the n-type and p-type GAAFETs. The forksheet transistor architecture can provide for reduced spacing between n-type and p-type S/D regions in adjacent GAAFETs relative to that in adjacent independent GAAFETs of the type illustrated in FIG. 9D. The forksheet transistor architecture can thus allow for increased transistor packing density relative to the packing of independent GAAFETs or increased active transistor width at the same transistor packing density as independent GAAFETs.

FIGS. 11A-11B are simplified perspective and cross-sectional views, respectively, of an example complementary field-effect-transistor (CFET) device. FIG. 11B is a cross-sectional view of the CFET device 1140 taken through the gate region and taken along the line B-B′ of FIG. 11A. The CFET device 1140 comprises vertically stacked GAAFETs 1142 and 1144. In FIGS. 11A and 11B, transistor 1142 is an n-type transistor, and transistor 1144 is a p-type transistor, but in other embodiments, a CFET device can comprise a p-type transistor located above an n-type transistor. The transistors 1142 and 1144 are formed on a substrate 1116 having a surface 1108. The substrate 1116 comprises an isolation region 1114 located on top of a bulk region 1118.

The n-type and p-type transistors 1142 and 1144 comprise a gate 1182 shared by both transistors that controls current flow between the source and drain regions of nanoribbons 1110 and 1120, respectively. The transistors 1142 and 1144 comprise three nanoribbons but the transistors of a CFET device can have any number of nanoribbons and different transistors of a CFET device can have a different number of nanoribbons. The n-type transistor 1142 comprises n-type source regions 1164 connected to n-type drain regions 1166 by channel regions 1165 and the p-type transistor 1144 comprises p-type source regions 1172 connected to p-type drain regions 1174 by channel regions 1173. The transistor stacking employed by the CFET device architecture can provide for improved transistor density in the x- and y-dimensions or increased transistor width at the same transistor density relative to other gate-all-around transistor architectures, such as those illustrated in FIGS. 9D, 10A, and 10B. In some embodiments, the CFET device 1140 can be formed monolithically, with the upper and lower transistors formed on the same substrate, or sequentially, with the lower transistor (e.g., 1144) formed on a first substrate and the upper transistor (e.g., 1142) formed on a second substrate, the upper transistor integrated with the lower transistor through transfer of the upper transistor from the second substrate to the first substrate.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

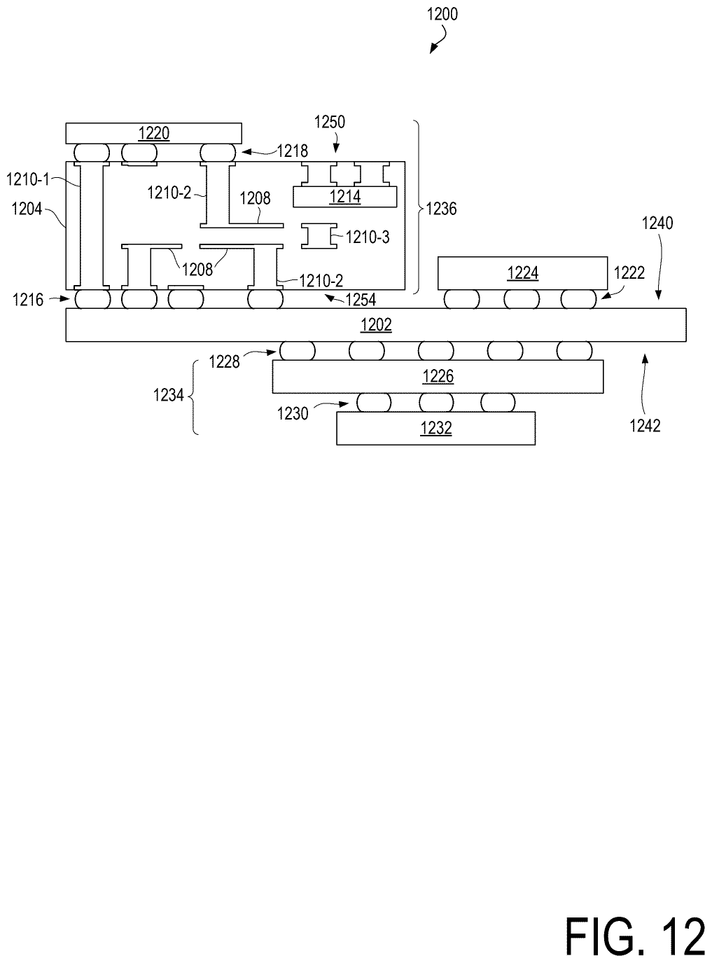

FIG. 12 is a cross-sectional side view of an integrated circuit device assembly 1200 that may include any of the microelectronic assemblies disclosed herein. The integrated circuit device assembly 1200 includes a number of components disposed on a circuit board 1202 (which may be a motherboard, system board, mainboard, etc.). The integrated circuit device assembly 1200 includes components disposed on a first face 1240 of the circuit board 1202 and an opposing second face 1242 of the circuit board 1202; generally, components may be disposed on one or both faces 1240 and 1242. Any of the integrated circuit components discussed below with reference to the integrated circuit device assembly 1200 may take the form of any suitable ones of the embodiments of the microelectronic assemblies disclosed herein.

In some embodiments, the circuit board 1202 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1202. In other embodiments, the circuit board 1202 may be a non-PCB substrate. The integrated circuit device assembly 1200 illustrated in FIG. 12 includes a package-on-interposer structure 1236 coupled to the first face 1240 of the circuit board 1202 by coupling components 1216. The coupling components 1216 may electrically and mechanically couple the package-on-interposer structure 1236 to the circuit board 1202, and may include solder balls (as shown in FIG. 12), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1216 may serve as the coupling components illustrated or described for any of the substrate assembly or substrate assembly components described herein, as appropriate.

The package-on-interposer structure 1236 may include an integrated circuit component 1220 coupled to an interposer 1204 by coupling components 1218. The coupling components 1218 may take any suitable form for the application, such as the forms discussed above with reference to the coupling components 1216. Although a single integrated circuit component 1220 is shown in FIG. 12, multiple integrated circuit components may be coupled to the interposer 1204; indeed, additional interposers may be coupled to the interposer 1204. The interposer 1204 may provide an intervening substrate used to bridge the circuit board 1202 and the integrated circuit component 1220.

The integrated circuit component 1220 may be a packaged or unpacked integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1220, a single monolithic integrated circuit die comprises solder bumps attached to contacts on the die. The solder bumps allow the die to be directly attached to the interposer 1204. The integrated circuit component 1220 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1220 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1220 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1220 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1204 may spread connections to a wider pitch or reroute a connection to a different connection. For example, the interposer 1204 may couple the integrated circuit component 1220 to a set of ball grid array (BGA) conductive contacts of the coupling components 1216 for coupling to the circuit board 1202. In the embodiment illustrated in FIG. 12, the integrated circuit component 1220 and the circuit board 1202 are attached to opposing sides of the interposer 1204; in other embodiments, the integrated circuit component 1220 and the circuit board 1202 may be attached to a same side of the interposer 1204. In some embodiments, three or more components may be interconnected by way of the interposer 1204.

In some embodiments, the interposer 1204 may be formed as a PCB, including multiple metal layers separated from one another by layers of dielectric material and interconnected by electrically conductive vias. In some embodiments, the interposer 1204 may be formed of an epoxy resin, a fiberglass-reinforced epoxy resin, an epoxy resin with inorganic fillers, a ceramic material, or a polymer material such as polyimide. In some embodiments, the interposer 1204 may be formed of alternate rigid or flexible materials that may include the same materials described above for use in a semiconductor substrate, such as silicon, germanium, and other group III-V and group IV materials. The interposer 1204 may include metal interconnects 1208 and vias 1210, including but not limited to through hole vias 1210-1 (that extend from a first face 1250 of the interposer 1204 to a second face 1254 of the interposer 1204), blind vias 1210-2 (that extend from the first or second faces 1250 or 1254 of the interposer 1204 to an internal metal layer), and buried vias 1210-3 (that connect internal metal layers).

In some embodiments, the interposer 1204 can comprise a silicon interposer. Through silicon vias (TSV) extending through the silicon interposer can connect connections on a first face of a silicon interposer to an opposing second face of the silicon interposer. In some embodiments, an interposer 1204 comprising a silicon interposer can further comprise one or more routing layers to route connections on a first face of the interposer 1204 to an opposing second face of the interposer 1204.

The interposer 1204 may further include embedded devices 1214, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1204. The package-on-interposer structure 1236 may take the form of any of the package-on-interposer structures known in the art. In embodiments where the interposer is a non-printed circuit board

The integrated circuit device assembly 1200 may include an integrated circuit component 1224 coupled to the first face 1240 of the circuit board 1202 by coupling components 1222. The coupling components 1222 may take the form of any of the embodiments discussed above with reference to the coupling components 1216, and the integrated circuit component 1224 may take the form of any of the embodiments discussed above with reference to the integrated circuit component 1220.

The integrated circuit device assembly 1200 illustrated in FIG. 12 includes a package-on-package structure 1234 coupled to the second face 1242 of the circuit board 1202 by coupling components 1228. The package-on-package structure 1234 may include an integrated circuit component 1226 and an integrated circuit component 1232 coupled together by coupling components 1230 such that the integrated circuit component 1226 is disposed between the circuit board 1202 and the integrated circuit component 1232. The coupling components 1228 and 1230 may take the form of any of the embodiments of the coupling components 1216 discussed above, and the integrated circuit components 1226 and 1232 may take the form of any of the embodiments of the integrated circuit component 1220 discussed above. The package-on-package structure 1234 may be configured in accordance with any of the package-on-package structures known in the art.

FIG. 13 is a block diagram of an example electrical device 1300 that may include one integrated circuit dies comprising the metal contacts comprising diffusion barrier layers as described herein. For example, any suitable ones of the components of the electrical device 1300 may include one or more of the integrated circuit device assemblies 1200, integrated circuit components 1220, integrated circuit devices 800, or integrated circuit dies 702 disclosed herein, and may be arranged in any of the microelectronic assemblies disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include an other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include an other input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items stated or recited as having a trait, feature, etc. means that all of the items in the list possess the stated or recited trait, feature, etc. For example, the phrase “individual of A, B, or C comprise a sidewall” or “respective of A, B, or C comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus, comprising: a substrate; an n-type semiconductor region comprising a semiconductor and an n-type dopant, the n-type semiconductor region part of or positioned adjacent to the substrate; a first layer comprising a first material, the first layer comprising a bottom portion and a sidewall portion; a second layer positioned adjacent to at least a portion of the first layer, the second layer comprising a first metal; a p-type semiconductor region comprising the semiconductor and a p-type dopant, the p-type semiconductor region part of or positioned adjacent to the substrate; a third layer comprising a second material that is different than the first material, a first portion of the third layer positioned adjacent to the p-type semiconductor region, a second portion of the third layer not positioned adjacent to the p-type semiconductor region; a fourth layer positioned adjacent to at least a portion of the third layer, the fourth layer comprising a second metal, an elemental composition of the second metal the same as or different from an elemental composition of the first metal; a fifth layer located on the second layer, the fifth layer comprising a third metal; and a sixth layer located on the fourth layer, the sixth layer comprising a fourth metal, an elemental composition of the fourth metal the same as or different from an elemental composition of the third metal.

Example 2 comprises the apparatus of Example 1, wherein the n-type semiconductor region and the p-type semiconductor region are part of the substrate, the n-type semiconductor region comprises a first portion of a surface of the substrate and the p-type semiconductor region comprises a second portion of the surface of the substrate.

Example 3 comprises the apparatus of Example 1, wherein the n-type semiconductor region and the p-type semiconductor region are positioned adjacent to the substrate.

Example 4 comprises the apparatus of Example 1, further comprising: a first fin extending upwards from the substrate, the n-type semiconductor region encompassing an end of the first fin; and a second fin extending upwards from the substrate, the p-type semiconductor region encompassing an end of the second fin.

Example 5 comprises the apparatus of any one of Examples 1-3, wherein the n-type dopant is a first n-type dopant and the p-type dopant is a first p-type dopant, the apparatus further comprising: one or more seventh layers located above and separate from the substrate, the one or more seventh layers comprising silicon and a second n-type dopant, the one or more seventh layers stacked vertically with respect to the substrate, the n-type semiconductor region positioned laterally adjacent to the one or more seventh layers, wherein an elemental composition of the first n-type dopant is the same as or different from an elemental composition of the second n-type dopant; and one or more eighth layers located above and separate from the substrate, the one or more eighth layers comprising silicon and a second p-type dopant, the one or more eighth layers stacked vertically with respect to the substrate, the p-type semiconductor region positioned laterally adjacent to the one or more eighth layers, wherein an elemental composition of the first p-type dopant is the same as or different from an elemental composition of the second p-type dopant.

Example 6 comprises the apparatus of Example 5, further comprising: one or more ninth layers comprising a fifth metal, individual of the one or more ninth layers positioned between adjacent seventh layers; one or more first dielectric layers, individual of the one or more first dielectric layers comprising oxygen, individual of the one or more first dielectric layers positioned between one of the one or more seventh layers and one of the one or more ninth layers; one or more tenth layers comprising a sixth metal, individual of the one or more tenth layers positioned between adjacent eighth layers; and one or more second dielectric layers, individual of the one or more second dielectric layers comprising oxygen, individual of the one or more second dielectric layers positioned between one of the one or more eighth layers and one of the one or more tenth layers.

Example 7 comprises the apparatus of Example 6, wherein individual of the one or more first dielectric layers further comprise: silicon; hafnium; hafnium and silicon; lanthanum; lanthanum and aluminum; zirconium; zirconium and silicon; tantalum; titanium; barium, strontium, titanium; barium and titanium; strontium and titanium; yttrium; aluminum; or lead, scandium, and tantalum.

Example 8 comprises the apparatus of Example 6, wherein individual of the one or more second dielectric layers further comprise: silicon; hafnium; hafnium and silicon; lanthanum; lanthanum and aluminum; zirconium; zirconium and silicon; tantalum; titanium; barium, strontium, titanium; barium and titanium; strontium and titanium; yttrium; aluminum; or lead, scandium, and tantalum.

Example 9 comprises the apparatus of Example 6, wherein the one or more seventh layers are stacked vertically with respect to the one or more eighth layers.

Example 10 comprises the apparatus of any one of Examples 1-9, wherein the third metal and the fourth metal are different.

Example 11 comprises the apparatus of any one of Examples 1-10, wherein an elemental composition of the first metal is the same as an elemental composition of the second metal.

Example 12 comprises the apparatus of any one of Examples 1-11, wherein the third metal comprises cobalt, titanium, gold, aluminum, molybdenum, chromium, or nickel.

Example 13 comprises the apparatus of any one of Examples 1-12, wherein the fourth metal comprises cobalt, titanium, gold, aluminum, molybdenum, chromium, or nickel.

Example 14 comprises the apparatus of any one of Examples 1˜4 and 9-13, wherein the n-type dopant is phosphorous, arsenic, or antimony.

Example 15 comprises the apparatus of any one of Examples 1-14, wherein the first metal is titanium.

Example 16 comprises the apparatus of any one of Examples 1-14, wherein the first metal is titanium and the second layer further comprises aluminum.

Example 17 comprises the apparatus of any one of Examples 1-14, wherein the first metal is titanium and the second layer further comprises aluminum and carbon.

Example 18 comprises the apparatus of any one of Examples 1-14, wherein the first metal is aluminum.

Example 19 comprises the apparatus of any one of Examples 1-14, wherein the first metal is scandium.

Example 20 comprises the apparatus of any one of Examples 1-14, wherein the first metal is erbium.

Example 21 comprises the apparatus of any one of Examples 1-14, wherein the first metal is yttrium.

Example 22 comprises the apparatus of any one of Examples 1-14, wherein the first metal is ytterbium.

Example 23 comprises the apparatus of any one of Examples 1-14, wherein the first metal is dysprosium.

Example 24 comprises the apparatus of any one of Examples 1-14, wherein the first metal is magnesium.

Example 25 comprises the apparatus of any one of Examples 1-14, wherein the first metal is magnesium and the second layer further comprises aluminum.

Example 26 comprises the apparatus of any one of Examples 1-25, wherein the first material comprises carbon.

Example 27 comprises the apparatus of any one of Examples 1-25, wherein the first material comprises carbon and titanium.

Example 28 comprises the apparatus of any one of Examples 1-25, wherein the first material comprises carbon, titanium, and aluminum.

Example 29 comprises the apparatus of any one of Examples 1-25, wherein the first material comprises titanium and phosphorous.

Example 30 comprises the apparatus of any one of Examples 1-25, wherein the first material comprises titanium and nitrogen.

Example 31 comprises the apparatus of any one of Examples 1-25, wherein the first material comprises titanium, carbon, and nitrogen.

Example 32 comprises the apparatus of any one of Examples 1-25, wherein the first material comprises titanium and boron.

Example 33 comprises the apparatus of any one of Examples 1-25, wherein the first material comprises aluminum and carbon.

Example 34 comprises the apparatus of any one of Examples 1-25, wherein the first material comprises aluminum and nitrogen.

Example 35 comprises the apparatus of any one of Examples 1-14, wherein the first material comprises titanium and carbon and the second layer comprises titanium.

Example 36 comprises the apparatus of any one of Examples 1-14, wherein the first material comprises titanium and carbon and the second layer comprises titanium and phosphorous.

Example 37 comprises the apparatus of any one of Examples 1-14, wherein the first material comprises titanium and carbon and the second layer comprises titanium, aluminum, and carbon.

Example 38 comprises the apparatus of any one of Examples 1-14, wherein the first material comprises titanium and carbon and the second layer comprises scandium.

Example 39 comprises the apparatus of any one of Examples 1-14, wherein the first material comprises carbon and the second layer comprises scandium.

Example 40 comprises the apparatus of any one of Examples 1˜4 and 9-13, wherein the p-type dopant is boron, gallium, or aluminum.

Example 41 comprises the apparatus of any one of Examples 1-40, wherein the second metal is titanium.

Example 42 comprises the apparatus of any one of Examples 1-41, wherein the second metal is molybdenum.

Example 43 comprises the apparatus of any one of Examples 1-41, wherein the second metal is tungsten.

Example 44 comprises the apparatus of any one of Examples 1-41, wherein the second metal is cobalt.

Example 45 comprises the apparatus of any one of Examples 1-41, wherein the second metal is nickel.

Example 46 comprises the apparatus of any one of Examples 1-41, wherein the second metal is platinum.

Example 47 comprises the apparatus of any one of Examples 1-41, wherein the second metal is molybdenum and the fourth layer further comprises boron.

Example 48 comprises the apparatus of any one of Examples 1-41, wherein the second metal is titanium and the fourth layer further comprises phosphorous.

Example 49 comprises the apparatus of any one of Examples 1-41, wherein the second metal is nickel and the fourth layer further comprises platinum.

Example 50 comprises the apparatus of any one of Examples 1-41, wherein the second metal is tantalum.

Example 51 comprises the apparatus of any one of Examples 1-41, wherein the second metal is niobium.

Example 52 comprises the apparatus of any one of Examples 1-51, wherein the second material comprises titanium and carbon.

Example 53 comprises the apparatus of any one of Examples 1-51, wherein the second material comprises carbon.

Example 54 comprises the apparatus of any one of Examples 1-51, wherein the second material comprises titanium, aluminum, and carbon.

Example 55 comprises the apparatus of any one of Examples 1-51, wherein the second material comprises titanium and phosphorous.

Example 56 comprises the apparatus of any one of Examples 1-51, wherein the second material comprises molybdenum and boron.

Example 57 comprises the apparatus of any one of Examples 1-51, wherein the second material comprises titanium and boron.

Example 58 comprises the apparatus of any one of Examples 1-51, wherein the second material comprises titanium, carbon, and nitrogen.

Example 59 comprises the apparatus of any one of Examples 1-51, wherein the second material comprises aluminum and carbon.

Example 60 comprises the apparatus of any one of Examples 1-51, wherein the second material comprises aluminum and nitrogen.

Example 61 comprises the apparatus of any one of Examples 1-41, wherein the second material comprises titanium and carbon and the fourth layer comprises molybdenum.

Example 62 comprises the apparatus of any one of Examples 1-41, wherein the second material comprises titanium and carbon and the fourth layer comprises titanium.

Example 63 comprises the apparatus of any one of Examples 1-41, wherein the second material comprises titanium and carbon and the fourth layer comprises nickel.

Example 64 comprises the apparatus of any one of Examples 1-41, wherein the second material comprises molybdenum and boron and the fourth layer comprises molybdenum.

Example 65 comprises the apparatus of any one of Examples 1-41, wherein the second material comprises titanium and boron and the fourth layer comprises molybdenum.

Example 66 comprises the apparatus of any one of Examples 1-65, wherein a thickness of the first layer is less than three nanometers.

Example 67 comprises the apparatus of any one of Examples 1-66, wherein a thickness of the third layer is less than three nanometers.

Example 68 comprises the apparatus of any one of Examples 1-67 wherein the semiconductor comprises silicon.

Example 69 comprises the apparatus of any one of Examples 1-67 wherein the semiconductor comprises silicon and germanium.

Example 70 comprises the apparatus of any one of Examples 1-67, wherein at least a portion of the first layer is positioned within a hole in a dielectric layer, the dielectric layer comprising silicon and oxygen.

Example 71 comprises the apparatus of Example 70, wherein the dielectric layer further comprises carbon, fluorine, or hydrogen.

Example 72 is an apparatus, comprising: a substrate comprising silicon; one or more first layers located above and separate from the substrate, the one or more first layers comprising silicon and an n-type dopant; a second layer positioned adjacent to and encompassing the one or more first layers along at least a portion of a length of individual of the one or more first layers, the second layer comprising a semiconductor and the n-type dopant; a third layer positioned adjacent to at least a portion of an outer surface of the second layer along at least a portion of a length of the second layer, the length of individual of the one or more first layers extending in a direction parallel to a surface of the substrate, the length of the second layer extending in the direction, the second layer comprising a first material; a fourth layer positioned adjacent to the third layer, the second layer comprising a first metal; a fifth layer located on the fourth layer, the third layer comprising a second metal; one or more sixth layers located above and separate from the substrate, the one or more sixth layers comprising silicon and a p-type dopant; a seventh layer positioned adjacent to and encompassing the one or more sixth layers along at least a portion of a length of individual of the one or more sixth layers, the seventh layer comprising the semiconductor and the p-type dopant, the seventh layer comprising a material different than the first material; an eighth layer positioned adjacent to at least a portion of an outer surface of the seventh layer along at least a portion of a length of the seventh layer, the length of individual of the one or more sixth layers extending in the direction, the eighth layer comprising a second material different than the first material; a ninth layer positioned adjacent to the eighth layer, the second layer comprising a third metal; and a tenth layer located on the ninth layer, the tenth layer comprising a fourth metal, an elemental composition of the fourth metal the same as or different from an elemental composition of the second metal.

Example 73 comprises the apparatus of Example 72, wherein the third layer encompasses an outer surface of a cross-sectional area of the second layer taken along a plane substantially perpendicular to the surface of the substrate, and the eighth layer encompasses an outer surface of a cross-sectional area of the seventh layer taken along the plane substantially perpendicular to the surface of the substrate.

Example 74 comprises the apparatus of any one of Examples 72-73, further comprising: one or more eleventh layers comprising a fifth metal, the one or more eleventh layers stacked vertically with respect to the surface of the substrate, individual of the one or more eleventh layers positioned between adjacent first layers along a portion of the length of the one or more first layers not encompassed by the second layer; one or more first dielectric layers, individual of the one or more first dielectric layers comprising oxygen, individual of the one or more first dielectric layers positioned between one of the one or more first layers and one of the one or more eleventh layers; one or more twelfth layers comprising a sixth metal, the one or more sixth layers stacked vertically with respect to the surface of the substrate, individual of the one or more twelfth layers positioned between adjacent sixth layers along a portion of the length of the one or more sixth layers not encompassed by the seventh layer; and one or more second dielectric layers, individual of the one or more second dielectric layers comprising oxygen, individual of the one or more second dielectric layers positioned between one of the one or more sixth layers and one of the one or more twelfth layers.

Example 75 comprises the apparatus of Example 74, wherein individual of the one or more first dielectric layers further comprise: silicon; hafnium; hafnium and silicon; lanthanum; lanthanum and aluminum; zirconium; zirconium and silicon; tantalum; titanium; barium, strontium, titanium; barium and titanium; strontium and titanium; yttrium; aluminum; or lead, scandium, and tantalum.

Example 76 comprises the apparatus of Example 74, wherein individual of the one or more second dielectric layers further comprise: silicon; hafnium; hafnium and silicon; lanthanum; lanthanum and aluminum; zirconium; zirconium and silicon; tantalum; titanium; barium, strontium, titanium; barium and titanium; strontium and titanium; yttrium; aluminum; or lead, scandium, and tantalum.

Example 77 comprises the apparatus of any one of Examples 72-76, wherein the one or more first layers are stacked vertically with respect to the one or more sixth layers.

Example 78 comprises the apparatus of any one of Examples 72-76, the one or more first layers are stacked vertically with respect to the surface of the substrate.

Example 79 comprises the apparatus of any one of Examples 72-78, wherein the second metal and the fourth metal are different.

Example 80 comprises the apparatus of any one of Examples 72-78, wherein an elemental composition of the first metal is the same as an elemental composition of the third metal.

Example 81 comprises the apparatus of any one of Examples 72-80, wherein the second metal comprises cobalt, titanium, gold, aluminum, molybdenum, chromium, or nickel.

Example 82 comprises the apparatus of any one of Examples 72-81, wherein the fourth metal comprises cobalt, titanium, gold, aluminum, molybdenum, chromium, or nickel.

Example 83 comprises the apparatus of any one of Examples 72-82, wherein the n-type dopant is phosphorous, arsenic, or antimony.

Example 84 comprises the apparatus of any one of Examples 72-83, wherein the first metal is titanium.

Example 85 comprises the apparatus of any one of Examples 72-83, wherein the first metal is titanium and the fourth layer further comprises aluminum.

Example 86 comprises the apparatus of any one of Examples 72-83, wherein the first metal is titanium and the fourth layer further comprises aluminum and carbon.

Example 87 comprises the apparatus of any one of Examples 72-83, wherein the first metal is aluminum.

Example 88 comprises the apparatus of any one of Examples 72-83, wherein the first metal is scandium.

Example 89 comprises the apparatus of any one of Examples 72-83, wherein the first metal is erbium.

Example 90 comprises the apparatus of any one of Examples 72-83, wherein the first metal is yttrium.

Example 91 comprises the apparatus of any one of Examples 72-83, wherein the first metal is ytterbium.

Example 92 comprises the apparatus of any one of Examples 72-83, wherein the first metal is dysprosium.

Example 93 comprises the apparatus of any one of Examples 72-83, wherein the first metal is magnesium.

Example 94 comprises the apparatus of any one of Examples 72-83, wherein the first metal is magnesium and the fourth layer further comprises aluminum.

Example 95 comprises the apparatus of any one of Examples 72-94, wherein the first material comprises carbon.

Example 96 comprises the apparatus of any one of Examples 72-94, wherein the first material comprises carbon and titanium.

Example 97 comprises the apparatus of any one of Examples 72-94, wherein the first material comprises carbon, titanium, and aluminum.

Example 98 comprises the apparatus of any one of Examples 72-94, wherein the first material comprises titanium and phosphorous.

Example 99 comprises the apparatus of any one of Examples 72-94, wherein the first material comprises titanium and nitrogen.

Example 100 comprises the apparatus of any one of Examples 72-94, wherein the first material comprises titanium, carbon, and nitrogen.

Example 101 comprises the apparatus of any one of Examples 72-94, wherein the first material comprises titanium and boron.

Example 102 comprises the apparatus of any one of Examples 72-94, wherein the first material comprises aluminum and carbon.

Example 103 comprises the apparatus of any one of Examples 72-94, wherein the first material comprises aluminum and nitrogen.

Example 104 comprises the apparatus of any one of Examples 72-83, wherein the first material comprises titanium and carbon and the fourth layer comprises titanium.

Example 105 comprises the apparatus of any one of Examples 72-83, wherein the first material comprises titanium and carbon and the fourth layer comprises titanium and phosphorous.

Example 106 comprises the apparatus of any one of Examples 72-83, wherein the first material comprises titanium and carbon and the fourth layer comprises titanium, aluminum, and carbon.

Example 107 comprises the apparatus of any one of Examples 72-83, wherein the first material comprises titanium and carbon and the fourth layer comprises scandium.

Example 108 comprises the apparatus of any one of Examples 72-83, wherein the first material comprises carbon and the fourth layer comprises scandium.

Example 109 comprises the apparatus of any one of Examples 72-108, wherein the p-type dopant is boron, gallium, or aluminum.

Example 110 comprises the apparatus of any one of Examples 72-109, wherein the third metal is titanium.

Example 111 comprises the apparatus of any one of Examples 72-109, wherein the third metal is molybdenum.

Example 112 comprises the apparatus of any one of Examples 72-109, wherein the third metal is tungsten.

Example 113 comprises the apparatus of any one of Examples 72-109, wherein the third metal is cobalt.

Example 114 comprises the apparatus of any one of Examples 72-109, wherein the third metal is nickel.

Example 115 comprises the apparatus of any one of Examples 72-109, wherein the third metal is platinum.

Example 116 comprises the apparatus of any one of Examples 72-109, wherein the third metal is molybdenum and the ninth layer further comprises boron.

Example 117 comprises the apparatus of any one of Examples 72-109, wherein the third metal is titanium and the ninth layer further comprises phosphorous.

Example 118 comprises the apparatus of any one of Examples 72-109, wherein the third metal is nickel and the ninth layer further comprises platinum.

Example 119 comprises the apparatus of any one of Examples 72-109, wherein the third metal is tantalum.

Example 120 comprises the apparatus of any one of Examples 72-109, wherein the third metal is niobium.

Example 121 comprises the apparatus of any one of Examples 72-120, wherein the second material comprises titanium and nitrogen.

Example 122 comprises the apparatus of any one of Examples 72-120, wherein the second material comprises carbon.

Example 123 comprises the apparatus of any one of Examples 72-120, wherein the second material comprises titanium, aluminum, and carbon.

Example 124 comprises the apparatus of any one of Examples 72-120, wherein the second material comprises titanium and phosphorous.

Example 125 comprises the apparatus of any one of Examples 72-120, wherein the second material comprises molybdenum and boron.

Example 126 comprises the apparatus of any one of Examples 72-120, wherein the second material comprises titanium and boron.

Example 127 comprises the apparatus of any one of Examples 72-120, wherein the second material comprises titanium, carbon, and nitrogen.

Example 128 comprises the apparatus of any one of Examples 72-120, wherein the second material comprises aluminum and carbon.

Example 129 comprises the apparatus of any one of Examples 72-120, wherein the second material comprises aluminum and nitrogen.

Example 130 comprises the apparatus of any one of Examples 72-109, wherein the second material comprises titanium and carbon and the ninth layer comprises molybdenum.

Example 131 comprises the apparatus of any one of Examples 72-109, wherein the second material comprises titanium and carbon and the ninth layer comprises titanium.

Example 132 comprises the apparatus of any one of Examples 72-109, wherein the second material comprises titanium and carbon and the ninth layer comprises nickel.

Example 133 comprises the apparatus of any one of Examples 72-109, wherein the second material comprises molybdenum and boron and the ninth layer comprises molybdenum.

Example 134 comprises the apparatus of any one of Examples 72-109, wherein the second material comprises titanium and boron and the ninth layer comprises molybdenum.

Example 135 comprises the apparatus of any one of Examples 72-134, wherein a thickness of the third layer is less than three nanometers.

Example 136 comprises the apparatus of any one of Examples 72-135, wherein a thickness of the eighth layer is less than three nanometers.

Example 137 comprises the apparatus of any one of Examples 72-136, wherein the semiconductor comprises silicon.

Example 138 comprises the apparatus of any one of Examples 72-136, wherein the semiconductor comprises silicon and germanium.

Example 139 comprises the apparatus of any one of Examples 72-138, wherein at least a portion of the third layer is located in a hole of a dielectric layer, the dielectric layer comprising silicon and oxygen.

Example 140 comprises the apparatus of Example 139, wherein the dielectric layer further comprises carbon, fluorine, or hydrogen.

Example 141 comprises the apparatus of any one of Examples 1-140 wherein the n-type semiconductor region is at least part of a source region or a drain region of a first field-effect transistor and the p-type semiconductor region is at least a part of a source region or a drain region of a second field-effect transistor.

Example 142 comprises the apparatus of any one of Examples 1-140 wherein the apparatus is a processor unit.

Example 143 comprises the apparatus of any one of Examples 1-140, wherein the apparatus is an integrated circuit component.

Example 144 comprises the apparatus of any one of Examples 1-140, wherein the apparatus is a wafer.

Example 145 comprises the apparatus of any one of Examples 1-140, wherein the apparatus further comprises: a printed circuit board; and an integrated circuit component attached to the printed circuit board, the integrated circuit component comprising the substrate, the second layer, and the third layer.

Example 146 comprises the apparatus of Example 145 wherein the integrated circuit component is a first integrated circuit component, the apparatus further comprising one or more second integrated circuit components attached to the printed circuit board.

Example 147 comprises the apparatus of Example 145, wherein the apparatus further comprises a housing enclosing the printed circuit board and the integrated circuit component.

Example 148 is a method, comprising: forming a first hole in a dielectric layer located on a substrate to expose an n-type semiconductor region comprising a semiconductor and an n-type dopant; forming a first layer comprising a first material, a first portion of the first layer positioned adjacent to the n-type semiconductor region, a second portion of the first layer located on one or more first sidewalls of the first hole; forming a second layer comprising a first metal, the second layer positioned adjacent to the first layer; forming a second hole in the dielectric layer to expose a p-type semiconductor region comprising the semiconductor and a p-type dopant; forming a third layer comprising a second material that is different than the first material, a first portion of the third layer positioned adjacent to the p-type semiconductor region, a second portion of the third layer located on one or more second sidewalls of the second hole; forming a fourth layer comprising a second metal, an elemental composition of the second metal the same as or different from an elemental composition of the first metal, the second layer positioned adjacent to the third layer; forming a fifth layer comprising a third metal, the fifth layer positioned adjacent to at least a portion of the second layer and at least partially filling the first hole; and forming a sixth layer comprising the third metal, the sixth layer positioned adjacent to at least a portion of the fourth layer and at least partially filling the second hole.

Example 149 comprises the method of Example 148, wherein the n-type semiconductor region and the p-type semiconductor region are part of the substrate and comprise portions of a surface of the substrate.

Example 150 comprises the method of Example 148, wherein the n-type semiconductor region and the p-type semiconductor region are positioned adjacent to the substrate.

Example 151 comprises the method of Example 148, wherein the n-type semiconductor region comprises at least a portion of a first fin extending upwards from a surface of the substrate and the p-type semiconductor region comprises at least a portion of a second fin extending upwards from the surface of the substrate.

Example 152 comprises the method of Example 148, wherein the n-type semiconductor region encompasses an end of a first fin extending upwards from a surface of the substrate, and the p-type semiconductor region encompasses an end of a second fin extending upwards from a surface of the substrate.

Example 153 comprises the method of any of Examples 148-152, wherein the third metal comprises cobalt, titanium, gold, aluminum, molybdenum, chromium, or nickel.

Example 154 comprises the method of any one of Examples 148-153, wherein the n-type dopant is phosphorous, arsenic, or antimony.

Example 155 comprises the method of any one of Examples 148-154, wherein the first metal is titanium.

Example 156 comprises the method of any one of Examples 148-154, wherein the first metal is titanium and the second layer further comprises aluminum.

Example 157 comprises the method of any one of Examples 148-154, wherein the first metal is titanium and the second layer further comprises aluminum and carbon.

Example 158 comprises the method of any one of Examples 148-154, wherein the first metal is aluminum.

Example 159 comprises the method of any one of Examples 148-154, wherein the first metal is scandium.

Example 160 comprises the method of any one of Examples 148-154, wherein the first metal is erbium.

Example 161 comprises the method of any one of Examples 148-154, wherein the first metal is yttrium.

Example 162 comprises the method of any one of Examples 148-154, wherein the first metal is ytterbium.

Example 163 comprises the method of any one of Examples 148-154, wherein the first metal is dysprosium.

Example 164 comprises the method of any one of Examples 148-154, wherein the first metal is magnesium.

Example 165 comprises the method of any one of Examples 148-164, wherein the first metal is magnesium and the second layer further comprises aluminum.

Example 166 comprises the method of any one of Examples 148-165, wherein the first material comprises carbon.

Example 167 comprises the method of any one of Examples 148-165, wherein the first material comprises carbon and titanium.

Example 168 comprises the method of any one of Examples 148-165, wherein the first material comprises carbon, titanium, and aluminum.

Example 169 comprises the method of any one of Examples 148-165, wherein the first material comprises titanium and phosphorous.

Example 170 comprises the method of any one of Examples 148-165, wherein the first material comprises titanium and nitrogen.

Example 171 comprises the method of any one of Examples 148-165, wherein the first material comprises titanium, carbon, and nitrogen.

Example 172 comprises the method of any one of Examples 148-165, wherein the first material comprises titanium and boron.

Example 173 comprises the method of any one of Examples 148-165, wherein the first material comprises aluminum and carbon.

Example 174 comprises the method of any one of Examples 148-165, wherein the first material comprises aluminum and nitrogen.

Example 175 comprises the method of any one of Examples 148-154, wherein the first material comprises titanium and carbon and the second layer comprises titanium.

Example 176 comprises the method of any one of Examples 148-154, wherein the first material comprises titanium and carbon and the second layer comprises titanium and phosphorous.

Example 177 comprises the method of any one of Examples 148-154, wherein the first material comprises titanium and carbon and the second layer comprises titanium, aluminum, and carbon.

Example 178 comprises the method of any one of Examples 148-154, wherein the first material comprises titanium and carbon and the second layer comprises scandium.

Example 179 comprises the method of any one of Examples 148-154, wherein the first material comprises carbon and the second layer comprises scandium.

Example 180 comprises the method of any one of Examples 148-179, wherein the p-type dopant is boron, gallium, or aluminum.

Example 181 comprises the method of any one of Examples 148-180, wherein the second metal is titanium.

Example 182 comprises the method of any one of Examples 148-180, wherein the second metal is molybdenum.

Example 183 comprises the method of any one of Examples 148-180, wherein the second metal is tungsten.

Example 184 comprises the method of any one of Examples 148-180, wherein the second metal is cobalt.

Example 185 comprises the method of any one of Examples 148-180, wherein the second metal is nickel.

Example 186 comprises the method of any one of Examples 148-180, wherein the second metal is platinum.

Example 187 comprises the method of any one of Examples 148-180, wherein the second metal is molybdenum and the fourth layer further comprises boron.

Example 188 comprises the method of any one of Examples 148-180, wherein the second metal is titanium and the fourth layer further comprises phosphorous.

Example 189 comprises the method of any one of Examples 148-180, wherein the second metal is nickel and the fourth layer further comprises platinum.

Example 190 comprises the method of any one of Examples 148-180, wherein the second metal is tantalum.

Example 191 comprises the method of any one of Examples 148-180, wherein the second metal is niobium.

Example 192 comprises the method of any one of Examples 148-191, wherein the second material comprises titanium and nitrogen.

Example 193 comprises the method of any one of Examples 148-191, wherein the second material comprises carbon.

Example 194 comprises the method of any one of Examples 148-191, wherein the second material comprises titanium, aluminum, and carbon.

Example 195 comprises the method of any one of Examples 148-191, wherein the second material comprises titanium and phosphorous.

Example 196 comprises the method of any one of Examples 148-191, wherein the second material comprises molybdenum and boron.

Example 197 comprises the method of any one of Examples 148-191, wherein the second material comprises titanium and boron.

Example 198 comprises the method of any one of Examples 148-191, wherein the second material comprises titanium, carbon, and nitrogen.

Example 199 comprises the method of any one of Examples 148-191, wherein the second material comprises aluminum and carbon.

Example 200 comprises the method of any one of Examples 148-191, wherein the second material comprises aluminum and nitrogen.

Example 201 comprises the method of any one of Examples 148-154, wherein the first layer comprises titanium and carbon and the fourth layer comprises molybdenum.

Example 202 comprises the method of any one of Examples 148-154, wherein the first layer comprises titanium and carbon and the fourth layer comprises titanium.

Example 203 comprises the method of any one of Examples 148-154, wherein the first layer comprises titanium and carbon and the fourth layer comprises nickel.

Example 204 comprises the method of any one of Examples 148-154, wherein the first layer comprises molybdenum and boron and the fourth layer comprises molybdenum.

Example 205 comprises the method of any one of Examples 148-154, wherein the first layer comprises titanium and boron and the fourth layer comprises molybdenum.

Example 206 comprises the method of any one of Examples 148-205, wherein the semiconductor comprises silicon.

Example 207 comprises the method of any one of Examples 148-205, wherein the semiconductor comprises silicon and germanium.

Example 208 comprises the method of any one of Examples 148-207, wherein the substrate is a wafer.

1. An apparatus, comprising:
a substrate;
an n-type semiconductor region comprising a semiconductor and an n-type dopant, the n-type semiconductor region part of or positioned adjacent to the substrate;
a first layer comprising a first material, the first layer comprising a bottom portion and a sidewall portion;
a second layer positioned adjacent to at least a portion of the first layer, the second layer comprising a first metal;
a p-type semiconductor region comprising the semiconductor and a p-type dopant, the p-type semiconductor region part of or positioned adjacent to the substrate;
a third layer comprising a second material that is different than the first material, a first portion of the third layer positioned adjacent to the p-type semiconductor region, a second portion of the third layer not positioned adjacent to the p-type semiconductor region;
a fourth layer positioned adjacent to at least a portion of the third layer, the fourth layer comprising a second metal, an elemental composition of the second metal the same as or different from an elemental composition of the first metal;
a fifth layer located on the second layer, the fifth layer comprising a third metal; and
a sixth layer located on the fourth layer, the sixth layer comprising a fourth metal, an elemental composition of the fourth metal the same as or different from an elemental composition of the third metal.

2. The apparatus of claim 1, further comprising:
a first fin extending upwards from the substrate, the n-type semiconductor region encompassing an end of the first fin; and
a second fin extending upwards from the substrate, the p-type semiconductor region encompassing an end of the second fin.

3. The apparatus of claim 1, wherein the n-type dopant is a first n-type dopant and the p-type dopant is a first p-type dopant, the apparatus further comprising:
one or more seventh layers located above and separate from the substrate, the one or more seventh layers comprising silicon and a second n-type dopant, the one or more seventh layers stacked vertically with respect to the substrate, the n-type semiconductor region positioned laterally adjacent to the one or more seventh layers, wherein an elemental composition of the first n-type dopant is the same as or different from an elemental composition of the second n-type dopant;
one or more eighth layers located above and separate from the substrate, the one or more eighth layers comprising silicon and a second p-type dopant, the one or more eighth layers stacked vertically with respect to the substrate, the p-type semiconductor region positioned laterally adjacent to the one or more eighth layers, wherein an elemental composition of the first p-type dopant is the same as or different from an elemental composition of the second p-type dopant;
one or more ninth layers comprising a fifth metal, individual of the one or more ninth layers positioned between adjacent seventh layers;
one or more first dielectric layers, individual of the one or more first dielectric layers comprising oxygen, individual of the one or more first dielectric layers positioned between one of the one or more seventh layers and one of the one or more ninth layers;
one or more tenth layers comprising a sixth metal, individual of the one or more tenth layers positioned between adjacent eighth layers; and
one or more second dielectric layers, individual of the one or more second dielectric layers comprising oxygen, individual of the one or more second dielectric layers positioned between one of the one or more eighth layers and one of the one or more tenth layers.

4. The apparatus of claim 1, wherein:
the first metal is titanium;
the first metal is titanium and the second layer further comprises aluminum;
the first metal is titanium and the second layer further comprises aluminum and carbon;
the first metal is aluminum;
the first metal is scandium;
the first metal is erbium;
the first metal is yttrium;
the first metal is ytterbium;
the first metal is dysprosium;
the first metal is magnesium; or
the first metal is magnesium and the second layer further comprises aluminum.

5. The apparatus of claim 1, wherein the first material comprises:
carbon;
carbon and titanium;
carbon, titanium, and aluminum;
titanium and phosphorous;
titanium and nitrogen;
titanium, carbon, and nitrogen;
titanium and boron;
aluminum and carbon; or
aluminum and nitrogen.

6. The apparatus of claim 1, wherein:
the second metal is titanium;
the second metal is molybdenum;
the second metal is tungsten;
the second metal is cobalt;
the second metal is nickel;
the second metal is platinum;
the second metal is molybdenum and the fourth layer further comprises boron;
the second metal is titanium and the fourth layer further comprises phosphorous;
the second metal is nickel and the fourth layer further comprises platinum;
the second metal is tantalum; or
the second metal is niobium.

7. The apparatus of claim 1, wherein the second material comprises:
titanium and carbon;
carbon;
titanium, aluminum, and carbon;
titanium and phosphorous;
molybdenum and boron;
titanium and boron;
titanium, carbon, and nitrogen;
aluminum and carbon; or
aluminum and nitrogen.

8. The apparatus of claim 1, wherein the apparatus further comprises:
a printed circuit board; and
an integrated circuit component attached to the printed circuit board, the integrated circuit component comprising the substrate, the second layer, and the third layer.

9. An apparatus, comprising:
a substrate comprising silicon;
one or more first layers located above and separate from the substrate, the one or more first layers comprising silicon and an n-type dopant;
a second layer positioned adjacent to and encompassing the one or more first layers along at least a portion of a length of individual of the one or more first layers, the second layer comprising a semiconductor and the n-type dopant, the second layer comprising a first material;
a third layer positioned adjacent to at least a portion of an outer surface of the second layer along at least a portion of a length of the second layer, the length of individual of the one or more first layers extending in a first direction parallel to a surface of the substrate, the length of the second layer extending in the first direction;
a fourth layer positioned adjacent to the third layer, the second layer comprising a first metal;
a fifth layer located on the fourth layer, the third layer comprising a second metal;
one or more sixth layers located above and separate from the substrate, the one or more sixth layers comprising silicon and a p-type dopant;
a seventh layer positioned adjacent to and encompassing the one or more sixth layers along at least a portion of a length of individual of the one or more sixth layers, the seventh layer comprising the semiconductor and the p-type dopant, the seventh layer comprising a second material different than the first material;
an eighth layer positioned adjacent to at least a portion of an outer surface of the seventh layer along at least a portion of a length of the seventh layer, the length of individual of the one or more sixth layers extending in a second direction parallel to the surface of the substrate, the length of the seventh layer extending in the second direction;
a ninth layer positioned adjacent to the eighth layer, the second layer comprising a third metal; and
a tenth layer located on the ninth layer, the tenth layer comprising a fourth metal, an elemental composition of the fourth metal the same as or different from an elemental composition of the second metal.

10. The apparatus of claim 9, wherein the third layer encompasses an outer surface of a cross-sectional area of the second layer taken along a plane substantially perpendicular to the surface of the substrate, and the eighth layer encompasses an outer surface of a cross-sectional area of the seventh layer taken along the plane substantially perpendicular to the surface of the substrate.

11. The apparatus of claim 9, further comprising:
one or more eleventh layers comprising a fifth metal, the one or more eleventh layers stacked vertically with respect to the surface of the substrate, individual of the one or more eleventh layers positioned between adjacent first layers along a portion of the length of the one or more first layers not encompassed by the second layer;
one or more first dielectric layers, individual of the one or more first dielectric layers comprising oxygen, individual of the one or more first dielectric layers positioned between one of the one or more first layers and one of the one or more eleventh layers;
one or more twelfth layers comprising a sixth metal, the one or more sixth layers stacked vertically with respect to the surface of the substrate, individual of the one or more twelfth layers positioned between adjacent sixth layers along a portion of the length of the one or more sixth layers not encompassed by the seventh layer; and
one or more second dielectric layers, individual of the one or more second dielectric layers comprising oxygen, individual of the one or more second dielectric layers positioned between one of the one or more sixth layers and one of the one or more twelfth layers.

12. The apparatus of claim 9, wherein the one or more first layers are stacked vertically with respect to the one or more sixth layers.

13. The apparatus of claim 9, wherein:
the first metal is titanium;
the first metal is titanium and the fourth layer further comprises aluminum;
the first metal is titanium and the fourth layer further comprises aluminum and carbon;
the first metal is aluminum;
the first metal is scandium;
the first metal is erbium;
the first metal is yttrium;
the first metal is ytterbium;
the first metal is dysprosium;
the first metal is magnesium; or
the first metal is magnesium and the fourth layer further comprises aluminum.

14. The apparatus of claim 9, wherein the first material comprises:
carbon;
carbon and titanium;
carbon, titanium, and aluminum;
titanium and phosphorous;
titanium and nitrogen;
titanium, carbon, and nitrogen;
titanium and boron;
aluminum and carbon; or
aluminum and nitrogen.

15. The apparatus of claim 9, wherein:
the third metal is titanium;
the third metal is molybdenum;
the third metal is tungsten;
the third metal is cobalt;
the third metal is nickel;
the third metal is platinum;
the third metal is molybdenum and the ninth layer further comprises boron;
the third metal is titanium and the ninth layer further comprises phosphorous;
the third metal is nickel and the ninth layer further comprises platinum;
the third metal is tantalum; or
the third metal is niobium.

16. The apparatus of claim 9, wherein the second material comprises:
titanium and carbon;
carbon;
titanium, aluminum, and carbon;
titanium and phosphorous;
molybdenum and boron;
titanium and boron;
titanium, carbon, and nitrogen;
aluminum and carbon; or
aluminum and nitrogen.

17. The apparatus of claim 9, wherein the apparatus further comprises:
a printed circuit board; and
an integrated circuit component attached to the printed circuit board, the integrated circuit component comprising the substrate, the second layer, and the third layer.

18. A method, comprising:
forming a first hole in a dielectric layer located on a substrate to expose an n-type semiconductor region comprising a semiconductor and an n-type dopant;
forming a first layer comprising a first material, a first portion of the first layer positioned adjacent to the n-type semiconductor region, a second portion of the first layer located on one or more first sidewalls of the first hole;
forming a second layer comprising a first metal, the second layer positioned adjacent to the first layer;
forming a second hole in the dielectric layer to expose a p-type semiconductor region comprising the semiconductor and a p-type dopant;
forming a third layer comprising a second material that is different than the first material, a first portion of the third layer positioned adjacent to the p-type semiconductor region, a second portion of the third layer located on one or more second sidewalls of the second hole;
forming a fourth layer comprising a second metal, an elemental composition of the second metal the same as or different from an elemental composition of the first metal, the second layer positioned adjacent to the third layer;
forming a fifth layer comprising a third metal, the fifth layer positioned adjacent to at least a portion of the second layer and at least partially filling the first hole; and
forming a sixth layer comprising the third metal, the sixth layer positioned adjacent to at least a portion of the fourth layer and at least partially filling the second hole, wherein the n-type semiconductor region encompasses an end of a first fin extending upwards from a surface of the substrate, and the p-type semiconductor region encompasses an end of a second fin extending upwards from a surface of the substrate.

19. The method of claim 18,
wherein:
the first metal is titanium;
the first metal is titanium and the second layer further comprises aluminum;
the first metal is titanium and the second layer further comprises aluminum and carbon;
the first metal is aluminum;
the first metal is scandium;
the first metal is erbium;
the first metal is yttrium;
the first metal is ytterbium;
the first metal is dysprosium;
the first metal is magnesium; or
the first metal is magnesium and the second layer further comprises aluminum; and
wherein first material comprises:
carbon;
carbon and titanium;
carbon, titanium, and aluminum;
titanium and phosphorous;
titanium and nitrogen;
titanium, carbon, and nitrogen;
titanium and boron;
aluminum and carbon; or
aluminum and nitrogen.

20. The method of claim 18,
wherein:
the second metal is titanium;
the second metal is molybdenum;
the second metal is tungsten;
the second metal is cobalt;
the second metal is nickel;
the second metal is platinum;
the second metal is molybdenum and the fourth layer further comprises boron;
the second metal is titanium and the fourth layer further comprises phosphorous;
the second metal is nickel and the fourth layer further comprises platinum;
the second metal is tantalum; or
the second metal is niobium; and
wherein the second material comprises:
titanium and carbon;
carbon;
titanium, aluminum, and carbon;
titanium and phosphorous;
molybdenum and boron;
titanium and boron;
titanium, carbon, and nitrogen;
aluminum and carbon; or
aluminum and nitrogen.
